(19) United States
(12) Patent Application Publication
(10) Pub. No.: US 2026/0006889 A1
(43) Pub. Date: Jan. 1, 2026

(54) SEMICONDUCTOR DEVICES AND METHODS OF MANUFACTURING THE SAME

(71) Applicant: Samsung Electronics Co., Ltd., Suwon-si, Gyeonggi-do (KR)

(72) Inventors: Junsu Kong, Suwon-si (KR); Woncheol Jeong, Suwon-si (KR); Kyungho Kim, Suwon-si (KR); Wangseop Lim, Suwon-si (KR); Youngchai Jung, Suwon-si (KR); Juseob Jeong, Suwon-si (KR); Kyubong Choi, Suwon-si (KR); Seojung Kim, Suwon-si (KR); Taehyun Ryu, Suwon-si (KR); Yeonho Park, Suwon-si (KR); Jinseok Lee, Suwon-si (KR)

(21) Appl. No.: 18/916,788

(22) Filed: Oct. 16, 2024

(30) Foreign Application Priority Data
Apr. 2, 2024 (KR) 10-2024-0044812

(51) Int. Cl. H10D 84/01; H10D 30/00; H10D 30/01; H10D 62/10; H10D 64/01; H10D 64/68; H10D 84/85

(52) U.S. Cl. CPC H10D 84/0181; H10D 30/0191; H10D 62/102; H10D 64/017; H10D 64/691; H10D 30/502; H10D 84/851; H10D 84/856

(57) ABSTRACT

A method of manufacturing a semiconductor device comprising: forming active structures; forming preliminary gate dielectric layers on the active structures; forming a first dipole layer including a first dipole material and a second dipole layer including a second dipole material on the preliminary gate dielectric layers; removing the first and second dipole layers in regions other than a first region of the active structures; removing a portion of the second dipole layer in regions other than a second region of the active structures, wherein each of the first and second regions includes at least two active structures, and the first region and the second region overlap to form an overlapping region; and performing a heat treatment process of diffusing the first and second dipole materials into the preliminary gate dielectric layers, wherein the overlapping region includes at least one of the active structures.

### CROSS-REFERENCE TO RELATED APPLICATIONS

This application claims benefit of priority to Korean Patent Application No. 10-2024-0044812 filed on Apr. 2, 2024 in the Korean Intellectual Property Office, the disclosure of which is incorporated herein by reference in its entirety.

### BACKGROUND OF THE INVENTION

Example embodiments of the present disclosure relate to semiconductor devices and methods of manufacturing the same.

As demand for high performance, high speed, and/or multifunctionality of a semiconductor device has increased, integration density of a semiconductor device has increased. Accordingly, scaling down of transistors in a semiconductor device has been progressed, such that methods for forming transistors having reduced sizes and providing various operating voltages have been researched.

### SUMMARY OF THE INVENTION

An example embodiment of the present disclosure may provide a semiconductor device having improved integration density and reliability, and a method of manufacturing a semiconductor device having reduced process difficulty and reduced process costs. The purposes and benefits of the embodiments of the present disclosure are not limited to the above-described purposes and benefits.

According to an example embodiment of the present disclosure, a method of manufacturing a semiconductor device, the method comprising: preparing a substrate including a plurality of active structures spaced apart from each other in a first direction; forming preliminary gate dielectric layers on at least a portion of the plurality of active structures; forming a plurality of dipole layers by forming a first dipole layer including a first dipole material and a second dipole layer including a second dipole material on the preliminary gate dielectric layers; removing the plurality of dipole layers in regions other than a first region of the plurality of active structures, wherein the first region includes at least two active structures among the plurality of active structures; removing a portion of the second dipole layer in regions other than a second region of the plurality of active structures, wherein the second region includes at least two active structures among the plurality of active structures, and the first region and the second region overlap each other to form an overlapping region; performing a heat treatment process of diffusing the first dipole material in the first dipole layer and the second dipole material in the second dipole layer into corresponding preliminary gate dielectric layers among the preliminary gate dielectric layers; and forming a gate structure by removing the plurality of dipole layers and forming a gate electrode, wherein the overlapping region includes at least one of the plurality of active structures, and wherein the first direction is parallel with an upper surface of the substrate.

According to an example embodiment of the present disclosure, a method of manufacturing a semiconductor device, the method comprising: preparing a substrate including a first active structure, a second active structure, a third active structure, and a fourth active structure spaced apart from each other in a first direction; forming a first gate dielectric layer on at least a portion of the first active structure, a second gate dielectric layer on at least a portion of the second active structure, a third gate dielectric layer on at least a portion of the third active structure, and a fourth gate dielectric layer on at least a portion of the fourth active structures; and forming a gate electrode extending around the first, second, third, and fourth gate dielectric layers, wherein the first gate dielectric layer includes a first dipole material, wherein the second gate dielectric layer includes a second dipole material different from the first dipole material, and wherein the first direction is parallel with an upper surface of the substrate.

According to an example embodiment of the present disclosure, a method of manufacturing a semiconductor device, the method comprising: alternately forming a plurality of sacrificial layers and a plurality of channel layers on a substrate; forming a plurality of active structures by partially removing the plurality of channel layers, the plurality of sacrificial layers, and the substrate, wherein each of the plurality of active structures includes an active region extending in a first direction parallel with an upper surface of the substrate; forming a sacrificial gate structure and gate spacer layers extending in a second direction intersecting the first direction on the plurality of active structures, wherein the second direction is parallel with the upper surface of the substrate; forming recess regions by removing a portion of each of the plurality of active structures exposed from the sacrificial gate structure, and forming source/drain regions in the recess regions; removing the sacrificial gate structures and the plurality of sacrificial layers; and forming a gate structure extending in the second direction on the active region in the each of the plurality of active structures, wherein the forming the gate structure includes: forming preliminary gate dielectric layers extending around the plurality of channel layers; forming a first dipole layer and a second dipole layer conformally extending along the preliminary gate dielectric layers in order; forming a first blocking layer in a first region of the plurality of active structures, and removing the first dipole layer and the second dipole layer from other regions of the plurality of active structures in which the first blocking layer is absent; removing the first blocking layer, forming a second blocking layer in a second region of the plurality of active structures, wherein the first region and the second region overlap each other to form an overlapping region, and removing the second dipole layer from other regions of the plurality of active structures in which the second blocking layer is absent, wherein the overlapping region includes at least one of the plurality of active structures; removing the second blocking layer, performing a heat treatment process of diffusing a first dipole material in the first dipole layer and a second dipole material in the second dipole layer into corresponding preliminary gate dielectric layers among the preliminary gate dielectric layers; and removing both the first dipole layer and the second dipole layer.

According to an example embodiment of the present disclosure, a semiconductor device, comprising: a substrate extending in a first direction; a plurality of transistors including a plurality of active regions in the substrate, wherein the plurality of transistors includes a first transistor and a second transistor, the plurality of active regions includes a first active region in the first transistor and a second active region in the second transistor, and the first active region and the second active region are spaced apart from each other in a second direction intersecting the first direction; a plurality of channel layers spaced apart from each other in a third direction perpendicular to an upper surface of the substrate on each of the plurality of active regions; and a gate structure including a gate electrode extending in the second direction on the substrate and extending around the plurality of channel layers, first gate dielectric layers between the plurality of channel layers on the first active region and the gate electrode, and second gate dielectric layers between the plurality of channel layers on the second active region and the gate electrode, wherein the first gate dielectric layers include a first dipole material that is configured to shift a threshold voltage in a positive direction, wherein the second gate dielectric layers include the first dipole material and a second dipole material that is configured to shift a threshold voltage in a negative direction, wherein the first direction and the second direction are parallel with the upper surface of the substrate.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a plan view illustrating a semiconductor device according to example embodiments of the present disclosure;

FIGS. 1B and 1C are cross-sectional views illustrating a semiconductor device according to example embodiments of the present disclosure;

FIG. 2A is enlarged views illustrating a semiconductor device according to example embodiments of the present disclosure;

FIG. 2B is enlarged views illustrating a semiconductor device according to example embodiments of the present disclosure;

FIG. 3 is a cross-sectional view illustrating a semiconductor device according to example embodiments of the present disclosure;

FIG. 4 is a cross-sectional view illustrating a semiconductor device according to example embodiments of the present disclosure;

FIG. 5A is a plan view illustrating a semiconductor device according to example embodiments of the present disclosure;

FIG. 5B is a cross-sectional view illustrating a semiconductor device according to example embodiments of the present disclosure;

FIGS. 6A and 6B are flowcharts illustrating a method of manufacturing a semiconductor device according to example embodiments of the present disclosure;

FIGS. 7A, 8A, 9A, 11A, 12A, 13A, 14A, 15A, 16A, and 17A are cross-sectional views illustrating processes of a method of manufacturing a semiconductor device according to example embodiments of the present disclosure;

FIGS. 7B, 8B, 9B, 10, and 11B are cross-sectional views illustrating processes of a method of manufacturing a semiconductor device according to example embodiments of the present disclosure;

FIGS. 12B, 13B, 14B, 15B, 16B, and 17B are enlarged views illustrating a semiconductor device according to example embodiments of the present disclosure;

FIG. 17C are enlarged views illustrating a portion of a region of a semiconductor device according to example embodiments of the present disclosure;

FIGS. 18A and 19A are cross-sectional views illustrating processes of a method of manufacturing a semiconductor device according to example embodiments of the present disclosure; and

FIGS. 18B and 19B are enlarged views illustrating a semiconductor device according to example embodiments of the present disclosure.

### DETAILED DESCRIPTION

Hereinafter, embodiments of the present disclosure will be described as follows with reference to the accompanying drawings.

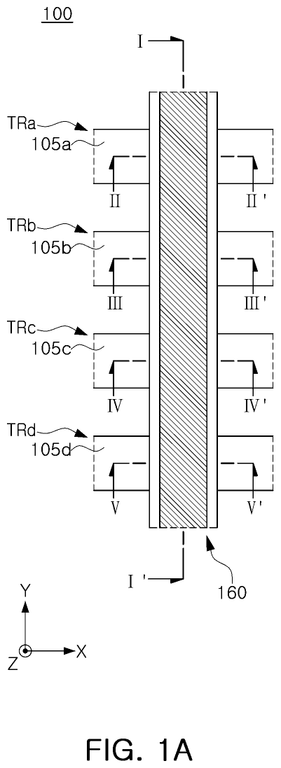

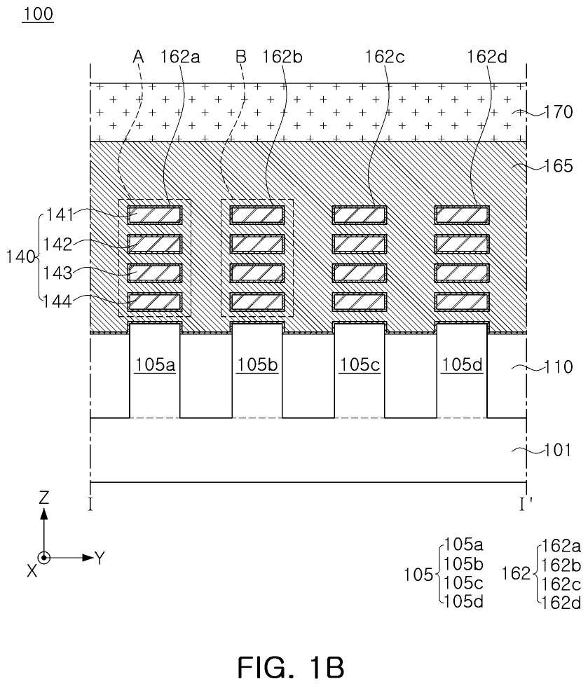

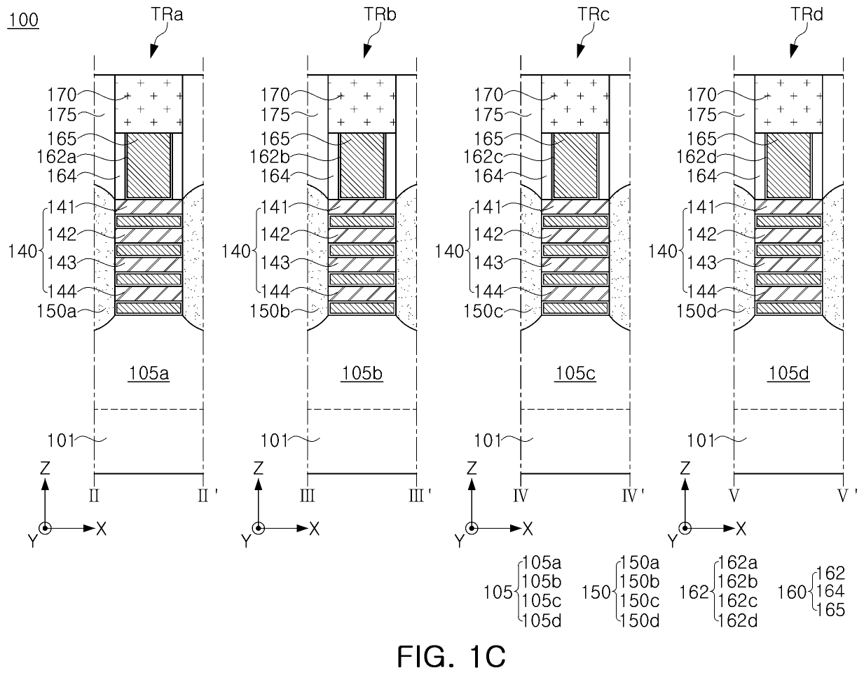

FIG. 1A is a plan view illustrating a semiconductor device according to example embodiments, illustrating a portion of components of the semiconductor device.

FIGS. 1B and 1C are cross-sectional views illustrating a semiconductor device according to example embodiments. FIG. 1B illustrates a cross-sectional surface of the semiconductor device in FIG. 1 taken along line I-I′. FIG. 1C illustrates cross-sectional surfaces of the semiconductor device in FIG. 1 taken along lines II-II′, III-III′, IV-IV′, and V-V′.

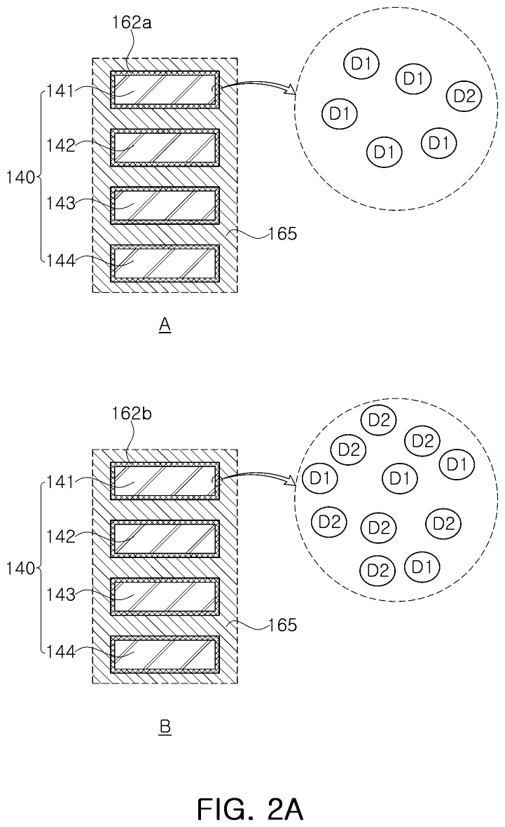

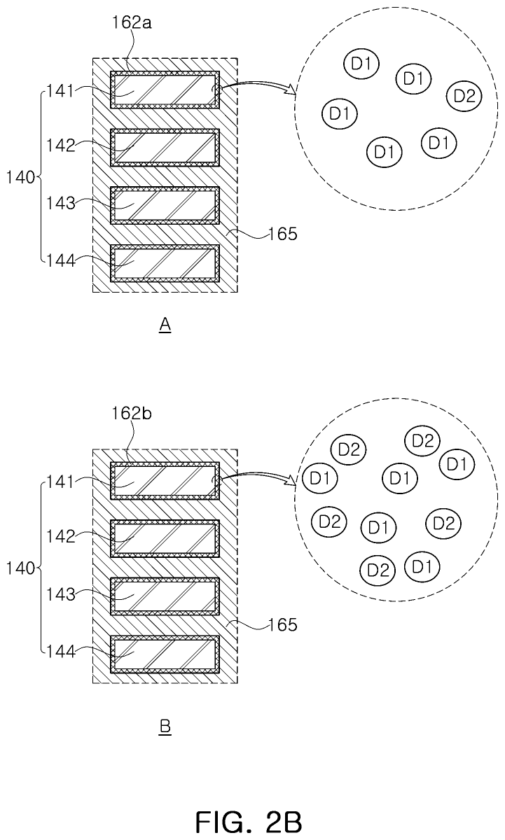

FIG. 2A is an enlarged view illustrating a semiconductor device according to example embodiments. FIG. 2A illustrates an enlarged view illustrating region “A” and region “B” of the semiconductor device in FIG. 1B according to an example embodiment, further illustrating an example embodiment of relative distribution of particular molecules in a portion of regions (a portion of the region A and a portion of the region B). The first and second dipole materials D1 and D2 illustrated in FIG. 2A illustrate an example embodiment for ease of description, and do not limit features, such as the amount, ratio, concentration, atomic fraction, mass fraction, or the like, of a first dipole material D1 and a second dipole material D2.

Referring to FIGS. 1A, 1B, 1C, and 2A, a semiconductor device 100 may include a substrate 101 including a plurality of active regions 105, channel structures 140 including first, second, third, and fourth channel layers 141, 142, 143, and 144 vertically disposed and spaced apart from each other on the plurality of active regions 105, respectively, a gate structure 160 extending by intersecting (e.g., overlapping in the Z-direction) the plurality of active regions 105 and including a gate dielectric layer 162 and a gate electrode 165, respectively, and source/drain regions 150 in contact with the channel structures 140. The number of the channel layers in the channel structure 140 is not limited to the descriptions above. The semiconductor device 100 may further include a device isolation layer 110, gate capping layers 170, and an interlayer insulating layer 175. Herein, the first, second, third, and fourth channel layers 141, 142, 143, and 144 may be in (or may be referred to as) a plurality of channel layers 141, 142, 143, and 144.

In the semiconductor device 100, each of the plurality of active regions 105 may have a fin structure, and the gate electrode 165 may be disposed between the plurality of active regions 105 and the channel structure 140, between the first, second, third, and fourth channel layers 141, 142, 143, and 144 of the channel structure 140, and on the channel structure 140 (e.g., on the first channel layer 141). Accordingly, the semiconductor device 100 may include transistors of multibridge channel FET (MBCFET™) structure, a gate-all-around type field effect transistor.

The substrate 101 may have an upper surface extending in the X-direction and the Y-direction. The substrate 101 may include a semiconductor material, such as a group IV semiconductor, a group III-V compound semiconductor, and/or a group II-VI compound semiconductor. For example, a group VI semiconductor may include silicon, germanium, and/or silicon-germanium. The substrate 101 may be provided as a bulk wafer, an epitaxial layer, a silicon on insulator (SOI) layer, or a semiconductor on insulator (SeOI) layer.

The substrate 101 may include a plurality of active regions 105 disposed on an upper portion. For example, the plurality of active regions 105 may be portions of the substrate 101 protruding upwardly in the Z-direction. The plurality of active regions 105 may be defined by the device isolation layer 110 in the substrate 101. The plurality of active regions 105 may extend in the first direction (e.g., the X-direction) and may be spaced apart from each other in the second direction (e.g., the Y-direction). For example, the plurality of active regions 105 may include first, second, third, and fourth active regions 105a, 105b, 105c, and 105d spaced apart from each other in the second direction (e.g., the Y-direction). The number of the active regions in the plurality of active regions 105 is not limited to the descriptions above. Depending on descriptions, the plurality of active regions 105 may be described as separate components, separate from the substrate 101. The plurality of active regions 105 may partially protrude to the device isolation layer 110, and an upper surface of each of the plurality of active regions 105 may be disposed on a level higher than a level of than an upper surface of the device isolation layer 110. For example, the plurality of active regions 105 may extend in the device isolation layer 110 in the Z-direction. The plurality of active regions 105 may include a portion of the substrate 101 or may include an epitaxial layer grown from the substrate 101. However, on both sides (e.g., opposite sides in a horizontal direction) of the gate structure 160, the plurality of active regions 105 may be partially recessed and recess regions may be formed, and source/drain regions 150 may be disposed in (on) the recess regions. The first direction (the X-direction) and the second direction (the Y-direction) may be collectively referred to as horizontal directions or respectively referred to as a first horizontal direction and a second horizontal direction. The Z-direction may be referred to as a vertical direction. The X-direction and Y-direction may be parallel with a lower surface of the substrate 101. The X-direction and Y-direction may intersect with (e.g., may be perpendicular to) each other. The Z-direction may be perpendicular to the lower surface of the substrate 101. As used herein, the term “and/or” includes any and all combinations of one or more of the associated listed items. A level or a height, herein, may refer to a distance from a lower layer or a lower substrate (e.g., the substrate 101) in the vertical direction (e.g., the Z-direction). For example, a higher level may refer to a farther distance from a lower surface of the substrate 101 in the Z-direction, and a lower level may refer to a closer distance from the lower surface of the substrate 101 in the Z-direction.

In example embodiments, each of the plurality of active regions 105 may include a well region including impurities. For example, in the case of a P-type transistor (PFET), a well region may include N-type impurities such as phosphorus (P), arsenic (AS), and/or antimony (Sb), and in the case of an N-type transistor (NFET), the well region may include P-type impurities such as boron (B), gallium (Ga), and/or indium (In). For example, the well region may be disposed at a predetermined depth from an upper surface of the active region 105. Herein, a depth may refer to a distance from a reference element toward the lower surface of the substrate 101 in the Z-direction. For example, the well region may be closer than the upper surface of the active region 105 to the lower surface of the substrate 101 in the Z-direction.

The semiconductor device 100 may include first, second, third, and fourth transistors TRa, TRb, TRc, and TRd disposed around (adjacent) the first, second, third, and fourth active regions 105a, 105b, 105c, and 105d, respectively. For example, the first, second, third, and fourth transistors TRa, TRb, TRc, and TRd may be on the first, second, third, and fourth active regions 105a, 105b, 105c, and 105d, respectively. In some embodiments, the first, second, third, and fourth transistors TRa, TRb, TRc, and TRd may be described to include first, second, third, and fourth active regions 105a, 105b, 105c, and 105d, respectively. The number of the transistors is not limited to the descriptions above. The first, second, third, and fourth transistors TRa, TRb, TRc, and TRd may be, for example, an N-type metal-oxide-semiconductor field effect transistor (NMOSFET) or a P-type metal-oxide-semiconductor field effect transistor (PMOSFET). The active region (e.g., the active region 105) included in the NMOSFET may include a well region including P-type impurities, and the active region (e.g., the active region 105) included in the PMOSFET may include a well region including N-type impurities.

The NMOSFET and PMOSFET adjacent to each other (in the Y-direction) may form a complementary MOSFET (CMOS). For example, in an example embodiment, the first transistor TRa, which is an N-type MOS field effect transistor, the second transistor TRb, which is a P-type MOS field effect transistor may form (e.g., may be included in) a complementary MOSFET (CMOS).

The device isolation layer 110 may define a plurality of active regions 105 in the substrate 101. The device isolation layer 110 may be formed, for example, by a shallow trench isolation (STI) process. The device isolation layer 110 may expose upper surfaces of the plurality of active regions 105 and may partially expose an upper portion of each of the plurality of active regions 105. In some example embodiments, the device isolation layer 110 may have a curved upper surface such that the device isolation layer 110 may have an increasing level (an increasing height) toward each of the plurality of active regions 105. The device isolation layer 110 may include (e.g., may be formed of) an insulating material. The device isolation layer 110 may include (e.g., may be), for example, oxide, nitride, and/or a combination thereof.

The gate structure 160 may be disposed to intersect (e.g., overlap in the Z-direction) with the plurality of active regions 105 and the channel structures 140 and to extend in the second direction, for example, the Y-direction. Functional channel regions of transistors may be formed in the plurality of active regions 105 and/or the channel structures 140 intersecting with the gate electrodes 165 of the gate structure 160. The gate structure 160 may include a gate electrode 165, gate dielectric layers 162 between the gate electrode 165 and (each of) the first, second, third, and fourth channel layers 141, 142, 143, and 144, and gate spacer layers 164 on side surfaces of the gate electrode 165.

The gate electrode 165 may (at least partially) fill a space between the first, second, third, and fourth channel layers 141, 142, 143, and 144 on the plurality of active regions 105 and extend to the channel structure 140. The gate electrode 165 may be spaced apart from (each of) the first, second, third, and fourth channel layers 141, 142, 143, and 144 by the gate dielectric layers 162. The gate electrode 165 may include a conductive material, for example, a metal nitride such as titanium nitride (TiN), tantalum nitride (TaN), and tungsten nitride (WN), a metal material such as aluminum (Al), tungsten (W), and molybdenum (Mo), and/or a semiconductor material such as doped polysilicon. In example embodiments, the gate electrode 165 may include two or more multiple layers.

The gate dielectric layers 162 may be disposed between the plurality of active regions 105 and the gate electrode 165 and between the channel structure 140 and the gate electrode 165 and may be disposed on (to cover) at least a portion of surfaces of the gate electrode 165. The gate dielectric layers 162 may extend around (e.g., surround) the channel structure 140 and may be on (may cover) upper surfaces of the plurality of active regions 105. For example, the gate dielectric layers 162 may be disposed to surround the entirety of surfaces other than uppermost surfaces of the gate electrode 165. The gate dielectric layers 162 may include first gate dielectric layers 162a disposed between the first active region 105a and the gate electrode 165 and the plurality of channel layers (the first, second, third, and fourth channel layers) 141, 142, 143, and 144 on the first active region 105a and the gate electrode 165, second gate dielectric layers 162b disposed between the second active region 105b and the gate electrode 165 and the plurality of channel layers (the first, second, third, and fourth channel layers) 141, 142, 143, and 144 on the second active region 105b and the gate electrode 165, third gate dielectric layers 162c disposed between the third active region 105c and the gate electrode 165 and the plurality of channel layers (the first, second, third, and fourth channel layers) 141, 142, 143, and 144 on the third active region 105c and the gate electrode 165, and fourth gate dielectric layers 162d disposed between the fourth active region 105d and the gate electrode 165 and the plurality of channel layers (the first, second, third, and fourth channel layers) 141, 142, 143, and 144 on the fourth active region 105d and the gate electrode 165.

The gate dielectric layers 162 may include, for example, oxide, nitride, and/or a high-K material. The high-K material may refer to a material having a dielectric constant higher than that of a silicon oxide film (SiO₂). The high-K material may include, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). In example embodiments, the gate dielectric layer 162 may include multiple films.

At least a portion of the first, second, third, and fourth gate dielectric layers 162a, 162b, 162c, and 162d may include a first dipole material D1 and/or a second dipole material D2. The first dipole material D1 and the second dipole material D2 may be materials shifting a threshold voltage of a transistor in opposite directions. For example, in an example embodiment, when the first dipole material D1 is a material shifting a threshold voltage Vth of a transistor in a positive (+) direction, the second dipole material D2 may be a material shifting a threshold voltage Vth of a transistor in a negative (−) direction. In another example embodiment, when the first dipole material D1 is a material shifting a threshold voltage Vth of a transistor in the negative (−) direction, the second dipole material D2 may be a material shifting a threshold voltage Vth of a transistor in the positive (+) direction. The first dipole material D1 and the second dipole material D2 may be selectively included in the first, second, third, and fourth gate dielectric layers 162a, 162b, 162c, and 162d, may be included in different amounts, or may not be included in example embodiments. The amount of the first dipole material D1 and second dipole material D2 in (each of) the first, second, third, and fourth gate dielectric layers 162a, 162b, 162c, and 162d may vary. The first dipole material D1 and/or second dipole material D2 may not be included in the first, second, third, and fourth gate dielectric layers 162a, 162b, 162c, and 162d.

Materials shifting a threshold voltage Vth of a transistor in the positive (+) direction (hereinafter, referred to as materials of a first group) may include (e.g., may be), for example, aluminum (Al), tantalum (Ta), tungsten (W), manganese (Mn), chromium (Cr), ruthenium (Ru), platinum (Pt), gallium (Ga), germanium (Ge), and/or gold (Au). Materials shifting a threshold voltage Vth of the transistor in the negative (−) direction (hereinafter, referred to as materials of a second group) may include (e.g., may be), for example, a rare earth element such as lanthanum (La), gadolinium (Gd), lutetium (Lu), yttrium (Y), and/or scandium (Sc).

When the gate dielectric layer (the gate dielectric layer 162) included in the N-type transistor includes materials of the first group (shifting the threshold voltage in the positive direction), an absolute value of the threshold voltage having a positive value may increase. Conversely, when the gate dielectric layer (the gate dielectric layer 162) included in the N-type transistor includes materials of the second group (shifting the threshold voltage in the negative direction), an absolute value of a threshold voltage having a positive value may decrease.

When the gate dielectric layer (the gate dielectric layer 162) included in the P-type transistor includes materials of the first group (shifting the threshold voltage in the positive direction), an absolute value of the threshold voltage having a negative value may decrease. Conversely, when the gate dielectric layer (the gate dielectric layer 162) included in the P-type transistor includes materials of the second group (shifting the threshold voltage in the negative direction), an absolute value of the threshold voltage having a negative value may increase.

The first transistor TRa and the fourth transistor TRd may be transistors of a first conductivity-type, and the second transistor TRb and the third transistor TRc may be transistors of a second conductivity-type different from the first conductivity-type. When the first conductivity-type is N-type, the second conductivity-type may be P-type, and when the first conductivity-type is P-type, the second conductivity-type may be N-type. An absolute value of the threshold voltage of the first transistor TRa may be greater than an absolute value of the threshold voltage of the fourth transistor TRd having the same conductivity-type. An absolute value of the second transistor TRb may be greater than an absolute value of the third transistor TRc having the same conductivity-type. As such, the first, second, third, and fourth transistors TRa, TRb, TRc, and TRd may be transistors driven under different threshold voltages. As an example embodiment thereof, the first, second, third, and fourth gate dielectric layers 162a, 162b, 162c, and 162d may include different amounts (e.g., zero amount) and/or ratios of the first dipole material D1 and the second dipole material D2.

Referring to FIG. 2A, the first gate dielectric layer 162a may include the first dipole material D1 and a (significantly) smaller amount (e.g., a smaller atomic fraction and/or a smaller mass fraction) of the second dipole material D2 than the first dipole material D1. In some embodiments, the first gate dielectric layer 162a may not include the second dipole material D2. The second gate dielectric layer 162b may include both the first dipole material D1 and the second dipole material D2, and an atomic fraction (or a mass fraction) of the second dipole material D2 may be larger than an atomic fraction (or a mass fraction) of the first dipole material D1. The above characteristics may be due to a process in example embodiments, which will be described in greater detail in the description of the manufacturing method described later. A difference between an atomic fraction of the second dipole material D2 in the second gate dielectric layer 162b and an atomic fraction of the first dipole material D1 included in the second gate dielectric layer 162b may be greater than an atomic fraction of the second dipole material D2 included in the first gate dielectric layer 162a. Although not specifically illustrated, the third gate dielectric layer 162c and the fourth gate dielectric layer 162d may include the first dipole material D1 and the second dipole material D2 in (extremely) small (smaller) amounts (e.g., the smaller atomic fraction and/or the smaller mass fraction) as compared to the amounts (e.g., the atomic fraction and/or the mass fraction) of the first dipole material D1 and the second dipole material D2 in the second gate dielectric layer 162b, respectively. In some embodiments, at least one of the third gate dielectric layer 162c and the fourth gate dielectric layer 162d may not include the first dipole material D1 and/or the second dipole material D2.

In an example embodiment, the first conductivity-type may be N-type, the second conductivity-type may be P-type, and accordingly, the first transistor TRa and the fourth transistor TRd may be NMOSFETs, and the second transistor TRb and the third transistor TRc may be PMOSFETs. In this case, the first dipole material D1 may include (e.g., may be) at least one of the materials of the first group and/or oxide, nitride, and/or oxynitride of at least one of the materials of the first group, and the first gate dielectric layer 162a may be included in the first transistor TRa, such that a threshold voltage of the first transistor TRa may be shifted in a positive direction. The second dipole material D2 may include (e.g., may be) at least one of the materials of the second group and/or oxide, nitride, and/or oxynitride of at least one of the materials of the second group, and the second gate dielectric layer 162b may be included in the second transistor TRb, such that a threshold voltage of the second transistor TRb may be shifted in a negative direction.

In an example embodiment, the first conductivity-type may be P-type, the second conductivity-type may be N-type, and accordingly, the first transistor TRa and the fourth transistor TRd may be configured as a PMOSFET, and the second transistor TRb and the third transistor TRc may be configured as an NMOSFET. In this case, the first dipole material D1 may include (e.g., may be) at least one of the materials of the second group and/or oxide, nitride, and/or oxynitride of at least one of the materials of the second group, and the first gate dielectric layer 162a may be included in the first transistor TRa, such that a threshold voltage of the first transistor TRa may be shifted in a negative direction. The second dipole material D2 may include (e.g., may be) at least one of the materials of the first group and/or oxide, nitride, and/or oxynitride of at least one of the materials of the first group, and the second gate dielectric layer 162b may be included in the second transistor TRb, such that a threshold voltage of the second transistor TRb may be shifted in a positive direction.

As such, the semiconductor device 100 may include first and fourth transistors TRa and TRd having a first conductivity-type, and second and third transistors TRb and TRc having a second conductivity-type. The first and second transistors TRa and TRb adjacent to each other may form a CMOS, and the third and fourth transistors TRc and TRd adjacent to each other may form another CMOS. The first and second transistors TRa and TRb having relatively large absolute values of the threshold voltage may have a relatively large current leakage prevention effect, and the third and fourth transistors TRc and TRd having relatively small absolute values of the threshold voltage may have a higher driving speed. For example, the first transistor TRa may have a larger absolute value of the threshold voltage than that of the fourth transistor TRd, and the second transistor TRb may have a larger absolute value of the threshold voltage than that of the third transistor TRc. The semiconductor device 100 may include various transistors having different conductivity-types and different threshold voltages in example embodiments, and may provide a semiconductor device having improved reliability and electrical properties.

The channel structures 140 may be disposed on the plurality of active regions 105, respectively, in regions in which the plurality of active regions 105 intersects (or overlaps in the Z-direction) the gate structure 160. Each of the channel structures 140 may include first, second, third, and fourth channel layers 141, 142, 143, and 144, which may be a plurality of channel layers spaced apart from each other in the Z-direction. The first, second, third, and fourth channel layers 141, 142, 143, and 144 may be disposed in order from an upper portion, and the first channel layer 141 may be the uppermost channel layer. The channel structures 140 may be (electrically) connected to a source/drain region 150. The channel structures 140 may have a width the same as or similar to that of the gate structures 160 in the X-direction, and may have a width the same as or smaller than that of the active region 105 in the Y-direction. In an example embodiment, in a cross-sectional surface in the Y-direction, the channel layer disposed in a lower portion of the first, second, third, and fourth channel layers 141, 142, 143, and 144 may have a width the same as or larger than that of the channel layer disposed in an upper portion. For example, the first (e.g., the uppermost) channel layer 141 may have the same width or a smaller width than each of the second, third, and fourth channel layers 142, 143, and 144. The number of the channel layers included in the channel structure 140 and the shape thereof may be varied in example embodiments. For example, the channel structure 140 may include three channel layers, two channel layers, or five or more channel layers.

The channel structures 140 may include (e.g., may be formed of) a semiconductor material, and may include, for example, silicon (Si), silicon germanium (SiGe), and/or germanium (Ge). The channel structures 140 may include (e.g., may be formed of) the same material as that of the active region 105, for example. In some example embodiments, the channel structures 140 may include an impurity region disposed in a region adjacent to the source/drain region 150.

The plurality of source/drain regions 150 may be disposed in recess regions partially recessed into an upper portion of each of the plurality of active regions 105 on both sides (e.g., opposite sides in a horizontal direction) of the gate structure 160. The recess regions may extend along side surfaces of the channel structures 140 and side surfaces of the gate dielectric layers 162. The plurality of source/drain regions 150 may include first source/drain regions 150a on a first active region 105a, second source/drain regions 150b on a second active region 105b, third source/drain regions 150c on a third active region 105c, and fourth source/drain regions 150d on the fourth active region 105d. The plurality of source/drain regions 150 may be disposed to be on (e.g., to cover) side surfaces each of the first, second, third, and fourth channel layers 141, 142, 143, and 144 of the channel structures 140 in the X-direction. Upper surfaces of the plurality of source/drain regions 150 may be disposed on a level the same as or higher level than a level of lower surfaces of the gate electrodes 165 on the channel structures 140, and the level may be varied in example embodiments. Side surfaces of the plurality of source/drain regions 150 may be varied in example embodiments. For example, in an example embodiment, side surfaces of the plurality of source/drain regions 150 may protrude in a direction of (toward) the gate structure 160 disposed between the plurality of channel layers 141, 142, 143, and 144. The plurality of source/drain regions 150 may be epitaxially grown regions, and each of the source/drain regions 150 may include a plurality of epitaxial layers. The epitaxially grown surface of each of the plurality of source/drain regions 150 may be in contact with the channel structures 140, the gate structure 160 and the interlayer insulating layer 175.

The source/drain regions 150 may include a semiconductor material, for example, silicon (Si) and/or germanium (Ge), and may further include dopants. For example, when the first conductivity-type is N-type and the second conductivity-type is P-type, dopants of the first and fourth source/drain regions 150a and 150d included in the N-type first and fourth transistors TRa and TRd may include (e.g., may be) phosphorus (P), arsenic AS, and/or antimony (Sb), and dopants of the second and third source/drain regions 150b and 150c included in the second and third transistors TRb and TRc of P-type may include (e.g., may be) boron (B), gallium (Ga), and/or indium (In).

The gate spacer layers 164 may be disposed on both side surfaces (e.g., opposite side surfaces in the X-direction) of the gate electrode 165 on the channel structure 140. The gate spacer layers 164 may separate (e.g., insulate) the source/drain regions 150 from the gate electrode 165. The gate spacer layers 164 may have a multilayer structure in example embodiments. The gate spacer layers 164 may include, for example, oxide, nitride, oxynitride, and/or, a low-K material. The low-K material may refer to a material having a dielectric constant lower than that of a silicon oxide film (SiO₂). The gate capping layer 170 may be disposed on the gate structure 160. The gate capping layer 170 may include, for example, oxide, nitride, and/or oxynitride.

The interlayer insulating layer 175 may be on (e.g., may cover or overlap) an upper surface of the device isolation layer 110 and the plurality of source/drain regions 150 on the device isolation layer 110. The interlayer insulating layer 175 may include, for example, oxide, nitride, oxynitride, and/or a low-K material. In example embodiments, the interlayer insulating layer 175 may include a plurality of insulating layers.

In a region not illustrated, the semiconductor device 100 may further include a contact structure electrically connected to the source/drain region 150 and upper interconnections electrically connected to the contact structure on the contact structure.

In the description of the example embodiments below, descriptions overlapping the aforementioned description with reference to FIGS. 1A, 1B, 1C, and 2A may not be provided.

FIG. 2B is an enlarged view illustrating a semiconductor device according to example embodiments. FIG. 2B illustrates enlarged modified example of regions “A” and region “B” of the semiconductor device in FIG. 1B, further illustrating an example embodiment of relative distribution of specific molecules in a portion of regions. The first and second dipole materials D1 and D2 illustrated in FIG. 2B illustrates an example embodiment for ease of description, and the amounts, ratios, concentrations, atomic fractions, mass fractions of the first dipole material D1 and the second dipole material D2 are not limited thereto. The description described with reference to FIG. 2B mainly includes the examples modified from those in the description described with reference to FIGS. 1A, 1B, 1C, and 2A.

Referring to FIG. 2B, as compared to the example embodiment in FIG. 2A, a difference between an atomic fraction of the first dipole material D1 and an atomic fraction of the second dipole material D2 in the second gate dielectric layer 162b may be (significantly) small (e.g., smaller than the first dipole material D1 in the first gate dielectric layer 162b). That is, the atomic fraction of the first dipole material D1 and the atomic fraction of the second dipole material D2 in the second gate dielectric layer 162b may be (substantially) the same as or similar to each other. Accordingly, in the example embodiment, the threshold voltage shift effect on the second transistor TRb including the second gate dielectric layer 162b may be smaller than in the example embodiment in FIG. 2A or may not occur. In the example embodiment, differently from the example embodiments in FIGS. 1A, 1B, 1C, and 2A, the first and second transistors TRa and TRb may have the same conductivity-type, a first conductivity-type, and the third and fourth transistors TRc and TRd may have a second conductivity-type different from the first conductivity-type. In the example embodiment, an absolute value of the threshold voltage of the first transistor TRa may be greater than an absolute value of the threshold voltage of the second transistor TRb.

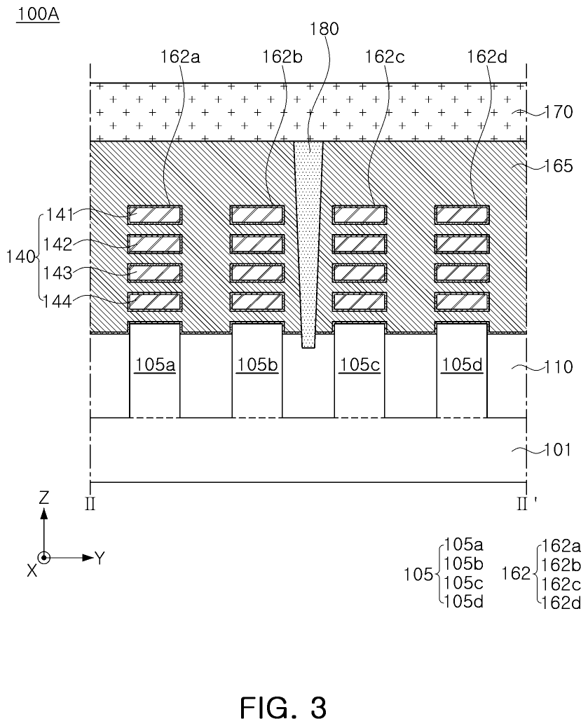

FIG. 3 is a cross-sectional view illustrating a semiconductor device according to example embodiments, illustrating the region corresponding to FIG. 1B.

Referring to FIG. 3, differently from the semiconductor device 100 in FIG. 1B, a semiconductor device 100A may further include a gate isolation pattern 180. The gate isolation pattern 180 may divide a gate electrode 165 into a portion on (e.g., covering or overlapping) a plurality of channel layers 141, 142, 143, and 144 on a first active region 105a and a second active region 105b, and a portion on (e.g., covering or overlapping) the plurality of channel layers 141, 142, 143, and 144 on a third active region 105c and a fourth active region 105d. For example, in a cross-sectional view, the gate isolation pattern 180 may be between the second active region 105b and the third active region 105c in the Y-direction. The position of the gate isolation pattern 180 and the number of the gate isolation pattern 180 may be varied in example embodiments. For example, the gate isolation pattern 180 may be disposed between the first active region 105a and the second active region 105b and/or between the third active region 105c and the fourth active region 105d. The gate isolation pattern 180 may include, for example, an insulating material, such as oxide, nitride, and/or oxynitride. The gate isolation pattern 180 may be disposed or formed in the example embodiment, and also in example embodiments described with reference to the other drawings.

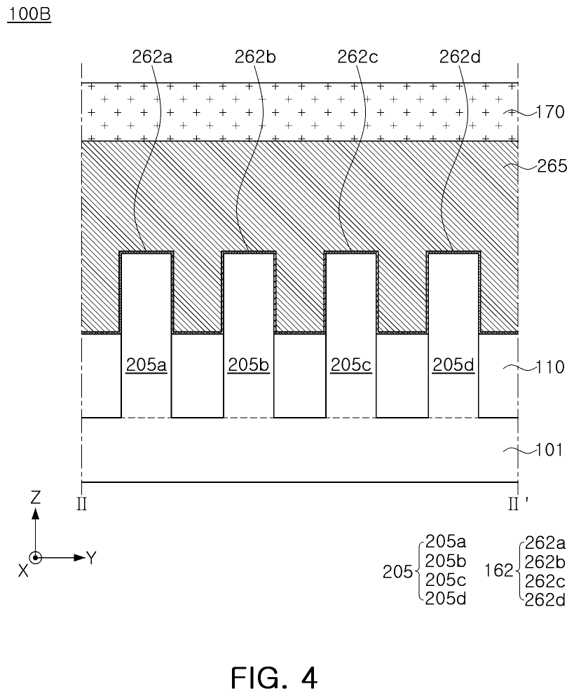

FIG. 4 is a cross-sectional view illustrating a semiconductor device according to example embodiments, illustrating the region corresponding to FIG. 1B.

Referring to FIG. 4, differently from the semiconductor device 100 in FIG. 1B, a semiconductor device 100B may not include channel structures 140, and the semiconductor device 100B may include FINFETs not including channel layers. In the semiconductor device 100B, channel regions of transistors may be disposed limitedly in first, second, third, and fourth active regions 205a, 205b, 205c, and 205d of a fin structure, which is an active structure. Also, channel layers may not be included in the gate electrodes 265. Also, the descriptions of the example embodiments in FIGS. 1A, 1B, 1C, 2A, 2B, and 3 may be applied to the components of the semiconductor device 100B. For example, the first gate dielectric layer 262a disposed between the first active region 205a and the gate electrode 265 may include the first dipole material D1, and accordingly, a threshold voltage of the transistor including the first active region 205a and the first gate dielectric layer 262a may be shifted in a positive direction as compared to a threshold voltage of other transistors (e.g., transistors not including or less including the first dipole material D1). The semiconductor device 100B may be further disposed in a region of the semiconductor device in other example embodiments.

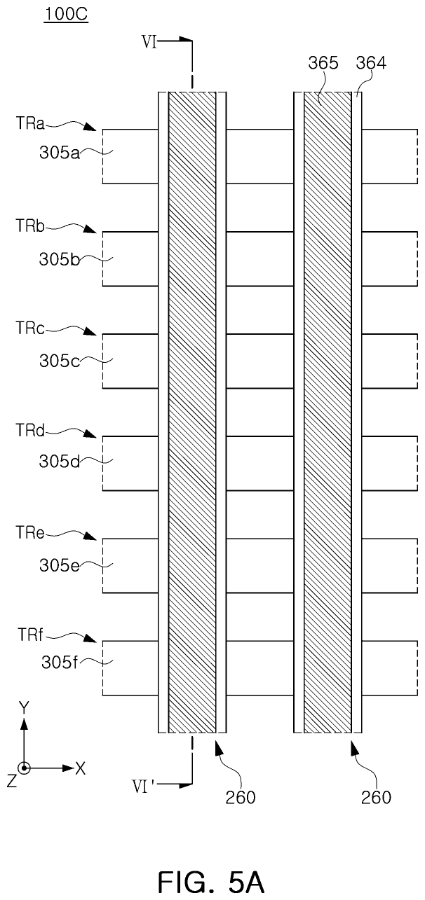

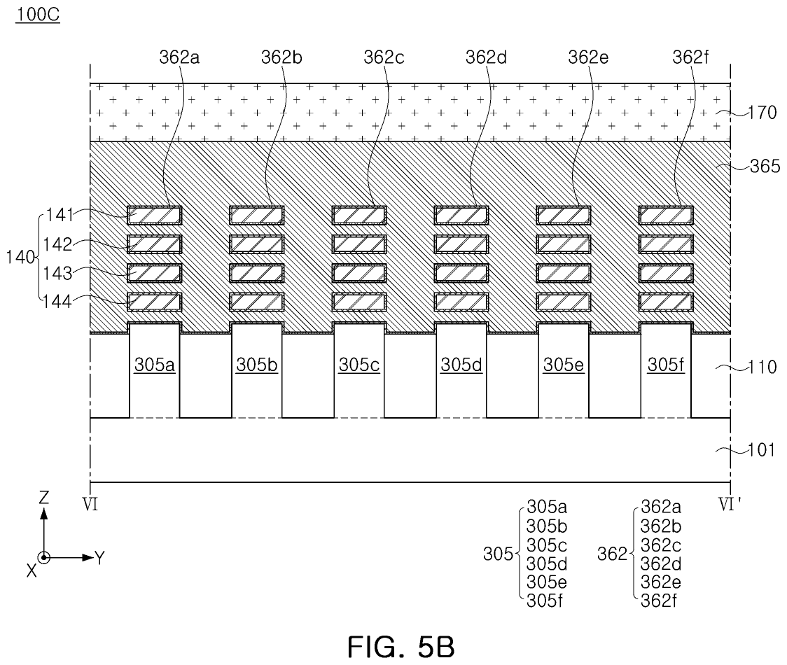

FIG. 5A is a plan view illustrating a semiconductor device according to example embodiments. For ease of description, FIG. 5A illustrates only a portion of components of the semiconductor device.

FIG. 5B is a cross-sectional view illustrating a semiconductor device according to example embodiments, illustrating a cross-sectional surface of the semiconductor device in FIG. 5A taken along line VI-VI′.

Referring to FIGS. 5A and 5B, a semiconductor device 100C may include first, second, third, fourth, fifth, and sixth transistors TRa, TRb, TRc, TRd, TRe, and TRf. Each of the first, second, third, fourth, fifth, and sixth transistors TRa, TRb, TRc, TRd, TRe, and TRf may have a first conductivity-type and/or a second conductivity-type, and transistors having the conductivity-types may be disposed complementarily. For example, in an example embodiment, the first, second, fifth and sixth transistors TRa, TRb, TRe, and TRf may have a first conductivity-type, and the third and fourth transistors TRc and TRd may have a second conductivity-type. In this case, the first, second, third, fourth, fifth, and sixth transistors TRa, TRb, TRc, TRd, TRe, and TRf may have a conductivity-type of N-type-N-type-P-type-P-type-N-type-N-type or P-type-P-type-N-type-N-type-P-type-P-type in order. In another example embodiment, the first, fourth and fifth transistors TRa, TRd, and TRe may have a first conductivity-type, and the second, third, and sixth transistors TRb, TRc, and TRf may have a second conductivity-type. In this case, the first, second, third, fourth, fifth, and sixth transistors TRa, TRb, TRc, TRd, TRc, and TRf may have a conductivity-type of N-type-P-type-P-type-N-type-N-type-P-type or P-type-N-type-N-type-P-type-P-type-N-type in order.

As for the first, second, third, fourth, fifth, and sixth gate dielectric layers 362a, 362b, 362c, 362d, 362e, and 362f included in the first, second, third, fourth, fifth, and sixth transistors TRa, TRb, TRc, TRd, TRe, and TRf included in semiconductor device 100B, respectively, gate dielectric layers (the first, second, third, fourth, fifth, and sixth gate dielectric layers 362a, 362b, 362c, 362d, 362c, and 362f) adjacent to each other may be configured similar to the examples (of the gate dielectric layers 162) described with reference to FIGS. 1A, 1B, 1C, 2A, and 2B. In the description below, the example embodiment in which the first, second, third, fourth, fifth, and sixth transistors TRa, TRb, TRc, TRd, TRe, and TRf may have conductivity-type of P-type-N-type-N-type-P-type-P-type-N-type in order will be described. In an example embodiment, the third gate dielectric layer 362c may include (a relatively larger amount of) a first dipole material D1 (and a relatively smaller or zero amount of a second dipole material D2) as illustrated in the enlarged view of region “A” in FIG. 2A, and the fourth gate dielectric layer 362d adjacent thereto may include both a first dipole material D1 and a second dipole material D2, as in the enlarged view region “B” in FIG. 2A. Unlike the enlarged view region “B” in FIG. 2A, an atomic fraction of the second dipole material D2 in the fourth gate dielectric layer 362d may be smaller than an atomic fraction of the first dipole material D1 in the fourth gate dielectric layer 362d. The first dipole material D1 may include materials of a first group, and the second dipole material D2 may include materials of a second group. Accordingly, a threshold voltage of the third transistor TRc, which is N-type, may be greater than a threshold voltage (of each) of the second and sixth transistors TRb and TRf, which are the same N-type transistors, and an absolute value of a threshold voltage of the fourth transistor TRd, which is a P-type, may be greater than an absolute value of a threshold voltage (of each) of the first and fifth transistors TRa and TRe, which are the same P-type transistors.

The characteristics of the first, second, third, fourth, fifth, and sixth transistors TRa, TRb, TRc, TRd, TRe, and TRf may be modified from the above, and overlapping descriptions may not be provided.

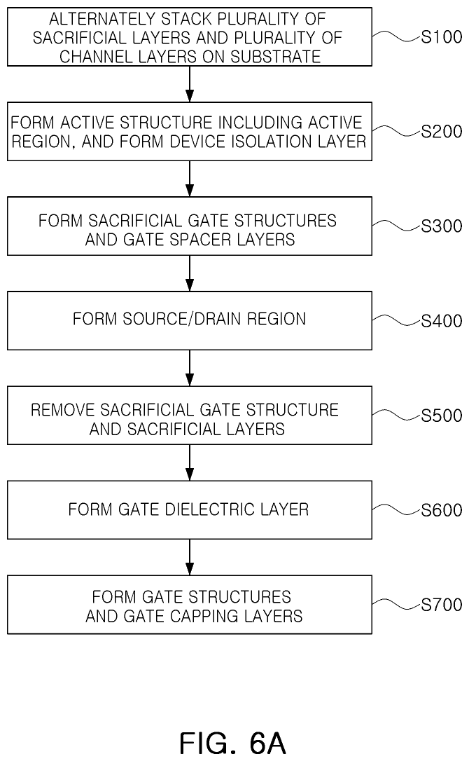

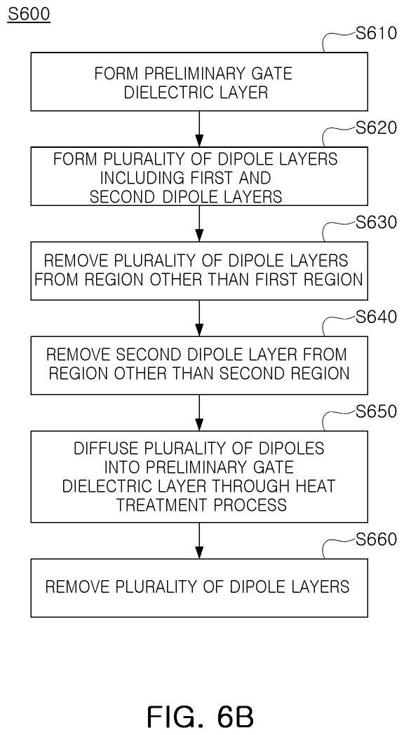

FIGS. 6A and 6B are flowcharts describing a method of manufacturing a semiconductor device according to example embodiments. FIG. 6B illustrates detailed processes of a portion of processes included in the flowcharts in FIG. 6A.

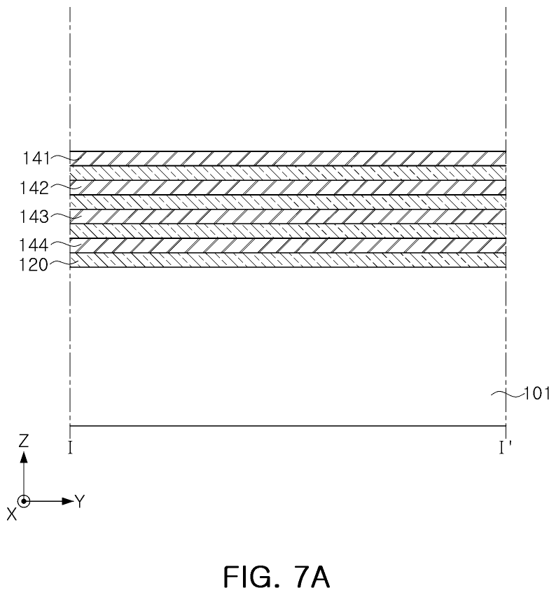

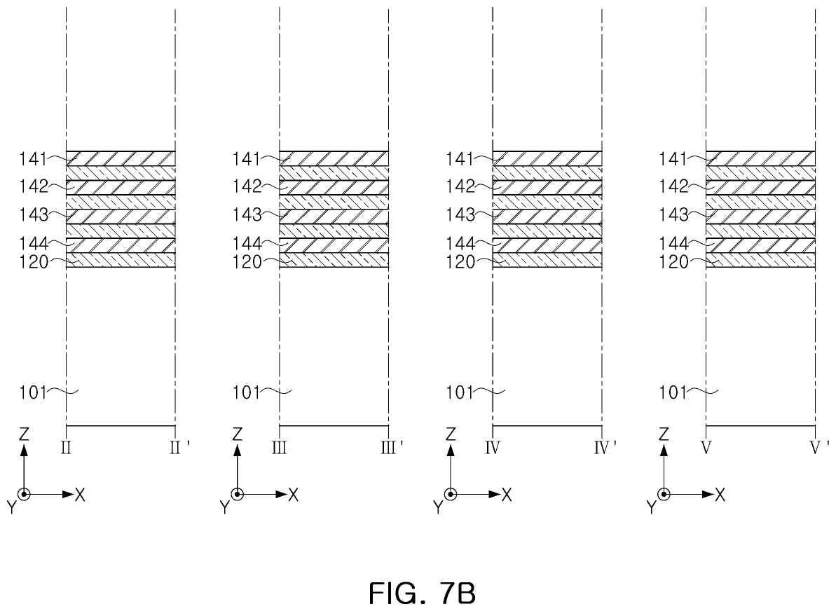

FIGS. 7A, 8A, 9A, 11A, 12A, 13A, 14A, 15A, 16A, and 17A are cross-sectional views illustrating processes of a method of manufacturing a semiconductor device in order according to example embodiments. FIGS. 7A, 8A, 9A, 11A, 12A, 13A, 14A, 15A, 16A, and 17A illustrate cross-sectional surfaces corresponding to FIG. 1B.

FIGS. 7B, 8B, 9B, 10, and 11B are cross-sectional views illustrating processes of a method of manufacturing a semiconductor device in order according to example embodiments. FIGS. 7B, 8B, 9B, 10, and 11B illustrate cross-sectional surfaces corresponding to FIG. 1C.

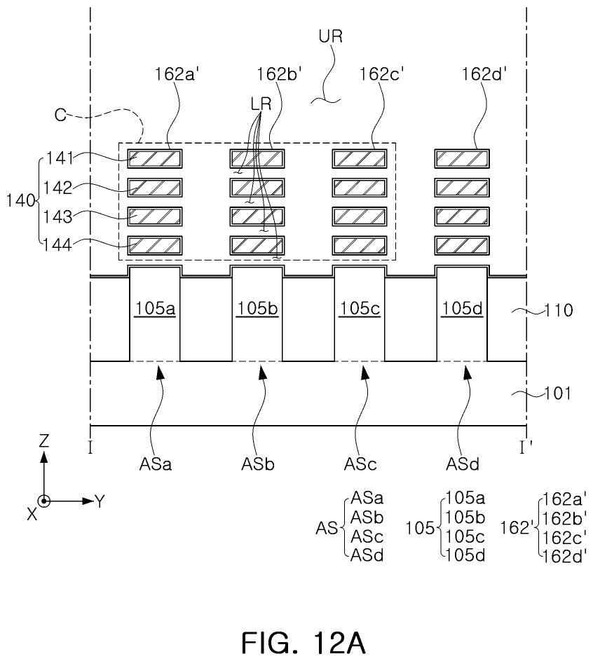

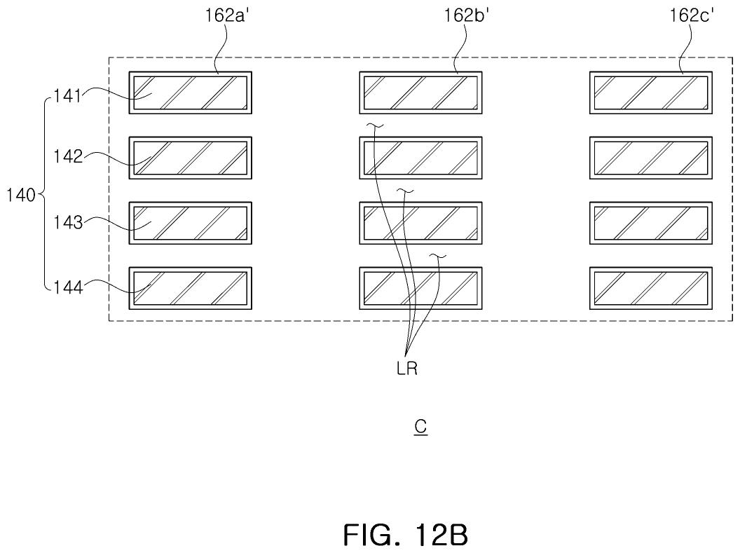

FIGS. 12B, 13B, 14B, 15B, 16B, and 17B are enlarged views illustrating semiconductor devices according to example embodiments.

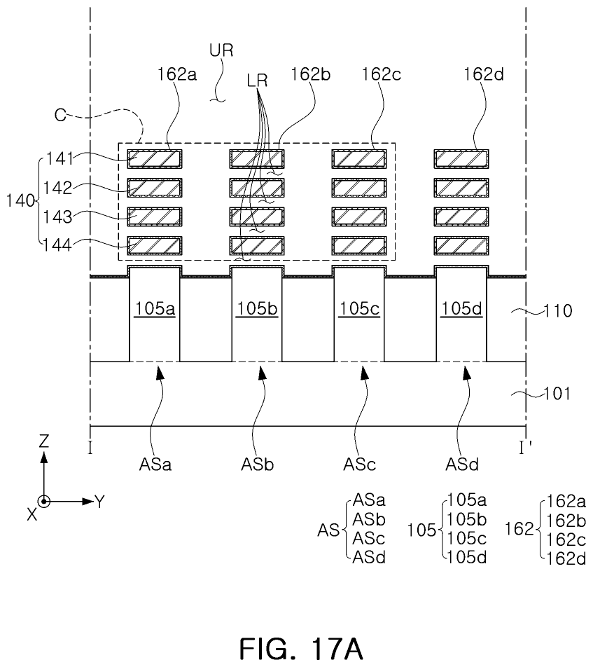

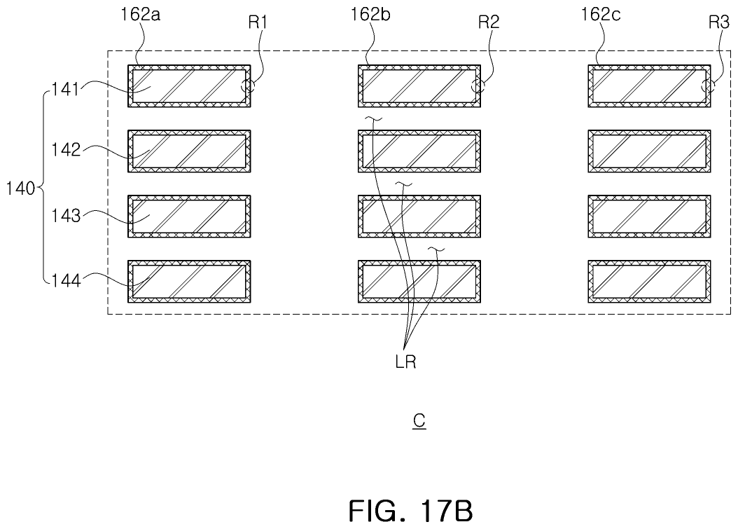

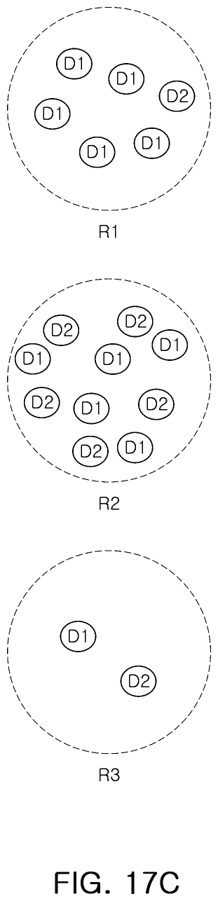

FIG. 17C are enlarged views illustrating a portion region of a semiconductor device according to example embodiments.

Unless otherwise indicated, the processes may be performed in order of reference numerals in the drawings, and the drawings of the same reference numerals may be performed simultaneously. For example, the processes in FIGS. 7A and 7B may be performed simultaneously.

Referring to FIGS. 7A and 7B together with FIG. 6A, a plurality of sacrificial layers 120 and a plurality of channel layers 141, 142, 143, and 144 may be stacked alternately on a substrate 101 (S100).

The substrate 101 may include, for example, silicon (Si), germanium (Ge), and/or silicon germanium (SiGe). The substrate 101 may include a bulk wafer, an epitaxial layer, a silicon on insulator (SOI) layer, or a semiconductor on insulator (SeOI) layer.

The plurality of channel layers 141, 142, 143, and 144 may include first, second, third, and fourth channel layers 141, 142, 143, and 144. The sacrificial layers 120 (below the first channel layer 141) may be replaced with gate dielectric layers 162 and/or gate electrodes 165 as illustrated in FIGS. 1B and 1C through a subsequent process. The sacrificial layers 120 may include (e.g., may be formed of) a material having etch selectivity for (with respect to) the first, second, third, and fourth channel layers 141, 142, 143, and 144, respectively. The first, second, third, and fourth channel layers 141, 142, 143, and 144 may include a material different from that of the sacrificial layers 120. The sacrificial layers 120 and the first, second, third, and fourth channel layers 141, 142, 143, and 144 may include, for example, a semiconductor material, such as silicon (Si), silicon germanium (SiGe), and/or germanium (Ge) and may include impurities. The impurities may be omitted from the sacrificial layers 120 and/or the first, second, third, and fourth channel layers 141, 142, 143, and 144. For example, the sacrificial layers 120 may include silicon germanium (SiGe), and the first, second, third, and fourth channel layers 141, 142, 143, and 144 may include silicon (Si).

The sacrificial layers 120 and the first, second, third, and fourth channel layers 141, 142, 143, and 144 may be formed by performing an epitaxial growth process from the (stacked) structure below the forming layer. The number of the channel layers alternately stacked with the sacrificial layers 120 may be varied in example embodiments.

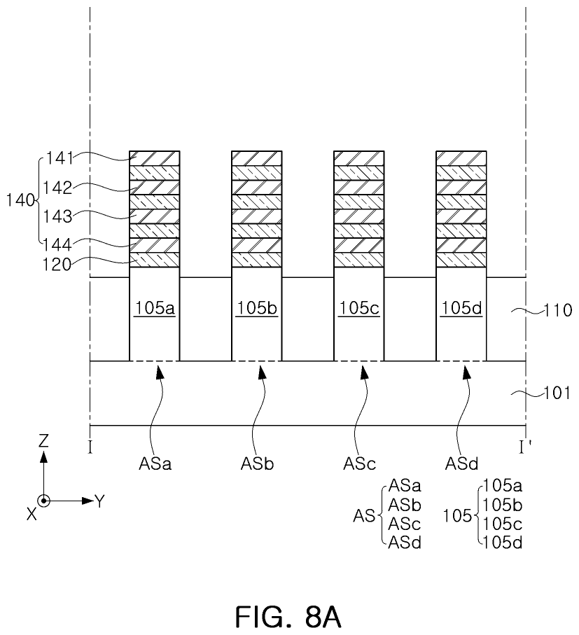

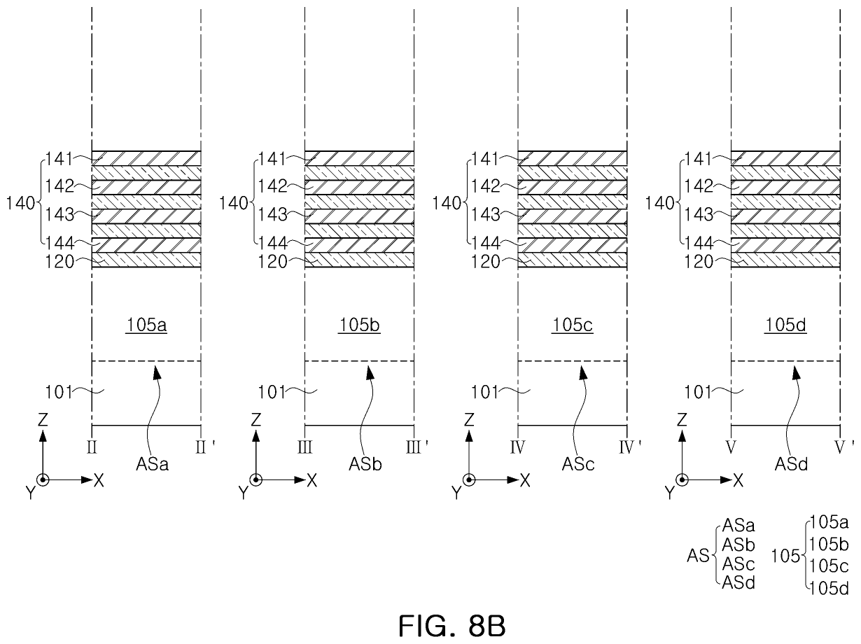

Referring to FIGS. 8A and 8B, together with FIG. 6A, a plurality of active structures AS including a plurality of active regions 105 may be formed by partially removing the sacrificial layers 120, the first, second, third, and fourth channel layers 141, 142, 143, and 144, and the substrate 101, and the device isolation layer 110 may be formed on the substrate 101 (and the plurality of active structures AS) (S200).

The plurality of active structures AS may include first, second, third, and fourth active structures ASa, ASb, ASc, and ASd extending in the first horizontal direction (e.g., the X-direction) and spaced apart from each other in the second horizontal direction (e.g., the Y-direction). The plurality of active regions 105 may include the first, second, third, and fourth active regions 105a, 105b, 105c, and 105d. The first, second, third, and fourth active structures ASa, ASb, ASc, and ASd may include first, second, third, and fourth active regions 105a, 105b, 105c, and 105d, respectively, and the active structures AS may include the (patterned) sacrificial layers 120, and the (patterned) first, second, third, and fourth channel layers 141, 142, 143, and 144. Side surfaces of the active structure AS in the Y-direction may be coplanar with each other, and may be disposed linearly. For example, the side surfaces of an active region 105 (e.g., the first active region 105a) among the plurality of active regions 105 may be aligned with side surfaces of the corresponding sacrificial layers 120 and side surfaces of the corresponding first, second, third, and fourth channel layers 141, 142, 143, and 144 in a horizontal direction (e.g., the Y-direction).

An insulating material may be filled in a region from which a portion of each of the active region 105, the sacrificial layers 120, and the first, second, third, and fourth channel layers 141, 142, 143, and 144 has been removed, and the insulating material may be partially removed such that (an upper portion of) each of the plurality of active regions 105 protrudes, thereby forming the device isolation layer 110. An upper surface of the device isolation layer 110 may be formed on a level lower than a level of an upper surface of each of the plurality of active regions 105.

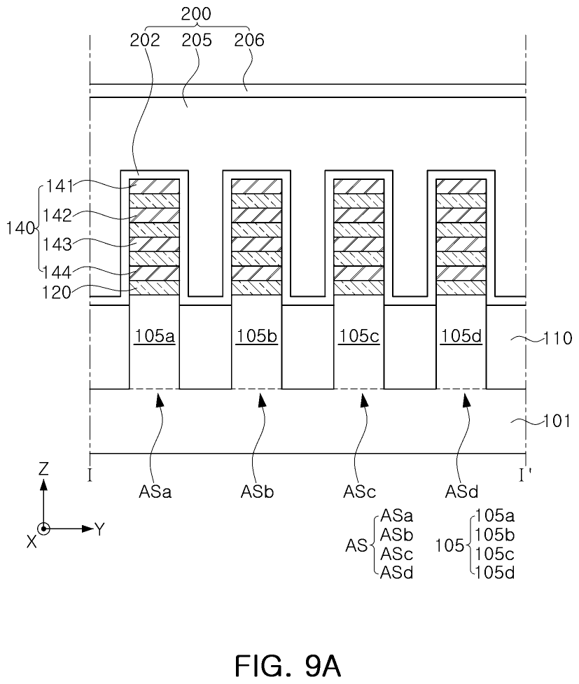

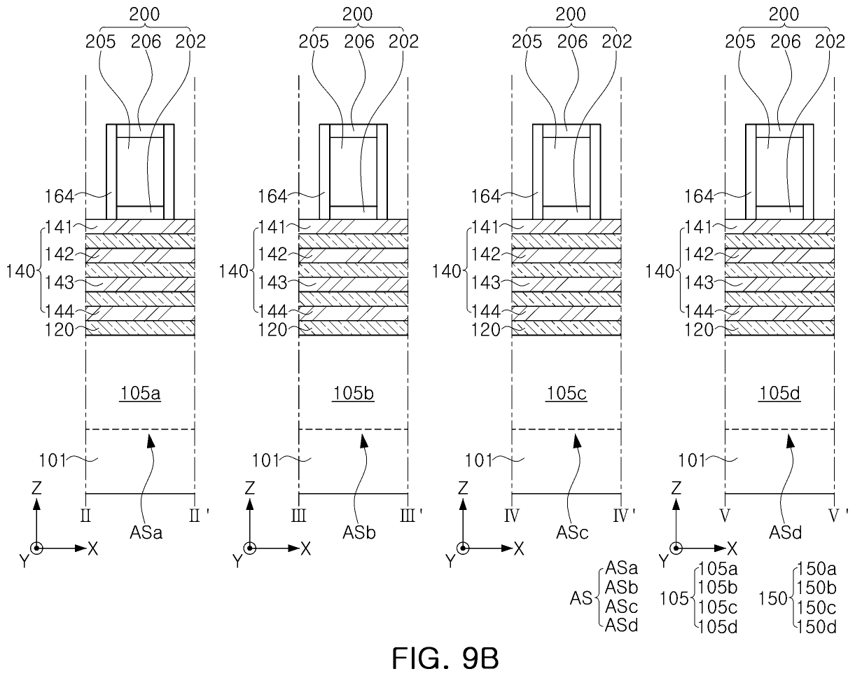

Referring to FIGS. 9A and 9B together with FIG. 6A, sacrificial gate structures 200 and gate spacer layers 164 may be formed on the plurality of active structures AS (S300).

Each of the sacrificial gate structures 200 may be configured as a sacrificial structure formed in a region in which the gate dielectric layers 162 and the gate electrode 165 are disposed on the channel structure 140 as illustrated in FIG. 1C through a subsequent process. The sacrificial gate structures 200 may have a line shape extending in one direction and intersecting (overlapping) the active structure AS. The sacrificial gate structures 200 may extend, for example, in the Y-direction. Each of the sacrificial gate structures 200 may include first and second sacrificial gate layers 202 and 205 and a mask pattern layer 206 stacked in order. The first and second sacrificial gate layers 202 and 205 may be patterned using the mask pattern layer 206

The first and second sacrificial gate layers 202 and 205 may be an insulating layer and a conductive layer, respectively, but an example embodiment thereof is not limited thereto, and the first and second sacrificial gate layers 202 and 205 may be integrated with each other. In some embodiments, the first sacrificial gate layer 202 may include silicon oxide, and the second sacrificial gate layer 205 may include polysilicon. The mask pattern layer 206 may include silicon oxide and/or silicon nitride.

The gate spacer layers 164 may be formed on both sidewalls (e.g., opposite sidewalls in the X-direction) of the sacrificial gate structures 200. The gate spacer layers 164 may include (e.g., may be formed of) a low-K material. In some embodiments, the gate spacer layers 164 may include, for example, SiO, SiN, SiCN, SiOC, SiON, and/or SiOCN.

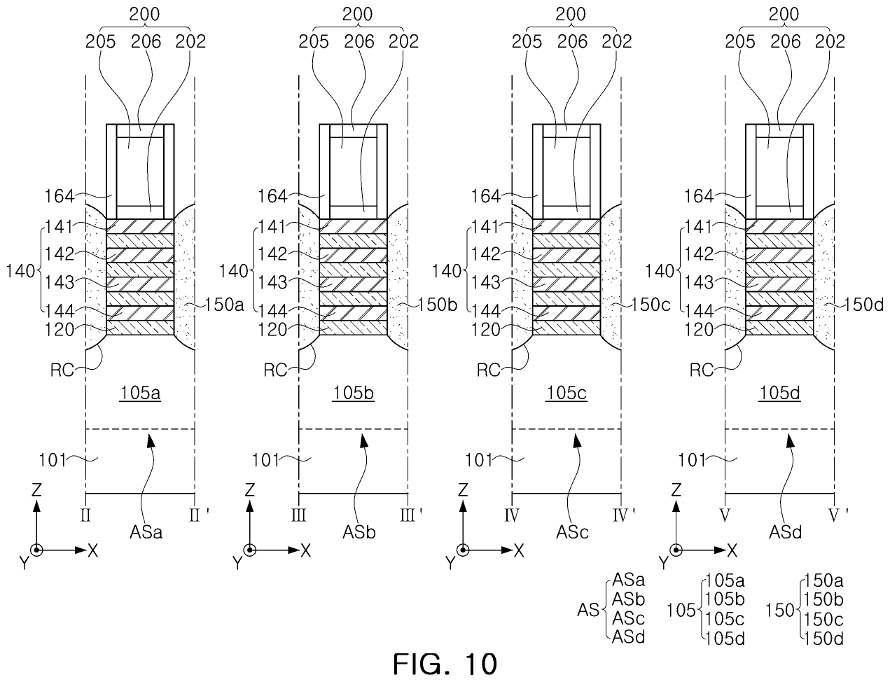

Referring to FIG. 10 together with FIG. 6A, recess regions RC penetrating (e.g., recessing at least a portion of) the active structure AS and exposing the active region 105 may be formed by performing an etching process using the sacrificial gate structures 200 as an etch mask, and the source/drain regions 150 may be formed in the recess regions RC (S400).

A recess region RC may be formed by at least partially removing portions of the sacrificial layers 120 and the first, second, third, and fourth channel layers 141, 142, 143, and 144 exposed from (not overlapping with) the sacrificial gate structures 200. Accordingly, the first, second, third, and fourth channel layers 141, 142, 143, and 144 may form channel structures 140 having a finite (e.g., predetermined) length in the X-direction.

In example embodiments, in this process, the sacrificial layers 120 may be selectively etched, for example, with respect to the channel structures 140, and may be removed to a predetermined depth from a side surface thereof in the X-direction. The sacrificial layers 120 may have side surfaces curved inwardly by etching the side surface thereof as described above.

The source/drain regions 150 may be formed in the recess regions RC, and may be formed by growing from side surfaces of the (corresponding) active region 105 and the (corresponding) channel structures 140, for example, by a selective epitaxial process. The source/drain region 150 may include a plurality of epitaxial layers. The source/drain region 150 may include impurities due to in-situ doping and may include a plurality of layers having different doping elements and/or doping concentrations.

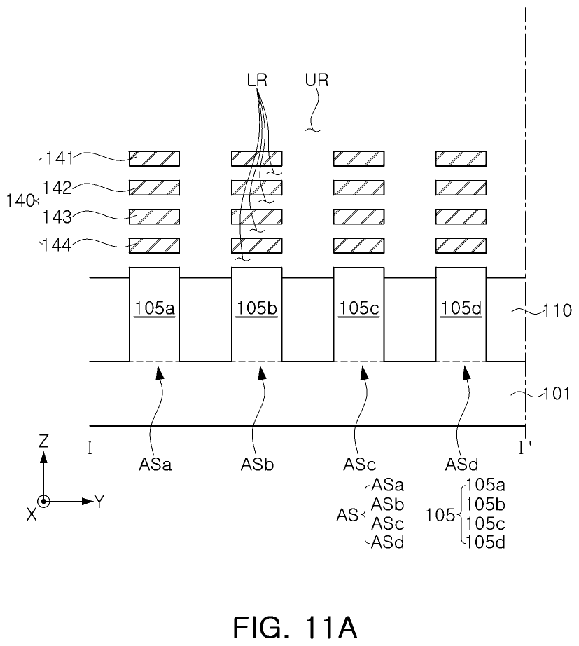

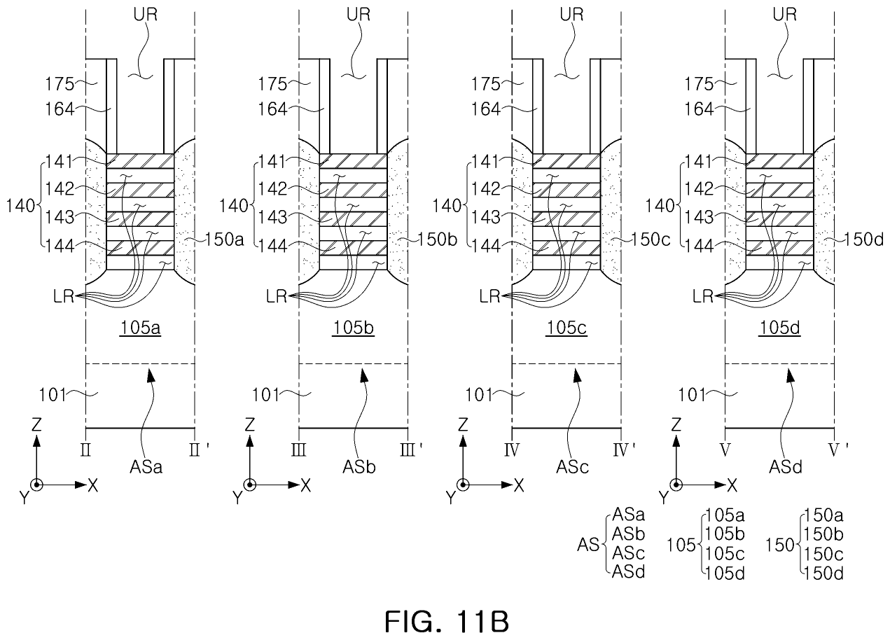

Referring to FIGS. 11A and 11B together with FIG. 6A, the interlayer insulating layer 175 may be partially formed, and the sacrificial gate structure 200 and the sacrificial layers 120 may be removed (S500).

The interlayer insulating layer 175 may be formed by forming an insulating film on (e.g., covering or overlapping) the sacrificial gate structures 200 and the source/drain region 150 and performing a planarization process.

The sacrificial gate structure 200 and the sacrificial layers 120 may be selectively removed with respect to the gate spacer layers 164 and the channel structures 140. First, upper gap regions UR may be formed by removing the sacrificial gate structure 200, and lower gap regions LR may be formed by removing the sacrificial layers 120 (exposed through the upper gap regions UR). For example, when the sacrificial layers 120 include silicon germanium (SiGe) and the channel structures 140 include silicon (Si), the sacrificial layers 120 may be selectively removed with respect to the channel structures 140 by performing a wet etching process. After the sacrificial layers 120 are removed, each of the plurality of active structures AS may be defined as a structure including an active region 105 extending in the first direction (e.g., X-direction) and a channel structure 140 on the active region 105. For example, the first active structure ASa may include a first active region 105a and a channel structure 140 (e.g., a plurality of channel layers 141, 142, 143, and 144 spaced apart from each other in the vertical direction (e.g., Z-direction)) on the first active region 105a.

Referring to FIGS. 12A and 12B together with FIGS. 6A and 6B, preliminary gate dielectric layers 162′ on (e.g., conformally covering) internal surfaces of the upper gap regions UR and the lower gap regions LR (S610) may be formed.

The preliminary gate dielectric layers 162′ may be on (e.g., may conformally cover) surfaces of the plurality of active regions 105 and the plurality of channel layers 141, 142, 143, and 144 exposed by the lower gap regions LR, and may be on (e.g., may cover) an upper surface of the first channel layer 141 exposed by the upper gap region UR. The preliminary gate dielectric layers 162′ may be formed using, for example, atomic layer deposition (ALD), chemical vapor deposition (CVD), and/or physical vapor deposition (PVD) processes. In example embodiments, the preliminary gate dielectric layers 162′ may include vacancy therein. The preliminary gate dielectric layers 162′ may include first, second, third, and fourth preliminary gate dielectric layers 162a′, 162a′, 162c′, and 162d′. The first, second, third, and fourth preliminary gate dielectric layers 162a′, 162a′, 162c′, and 162d′ may be formed on the first, second, third, and fourth active structures ASa, ASb, ASc, and ASd, respectively.

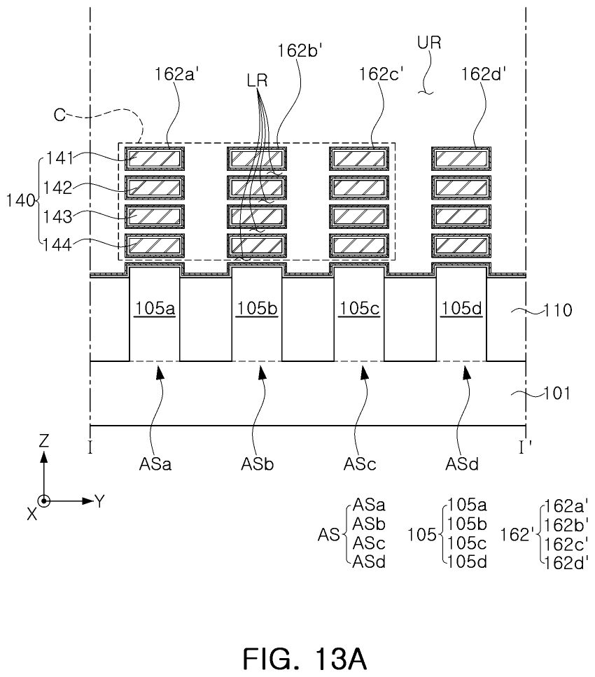

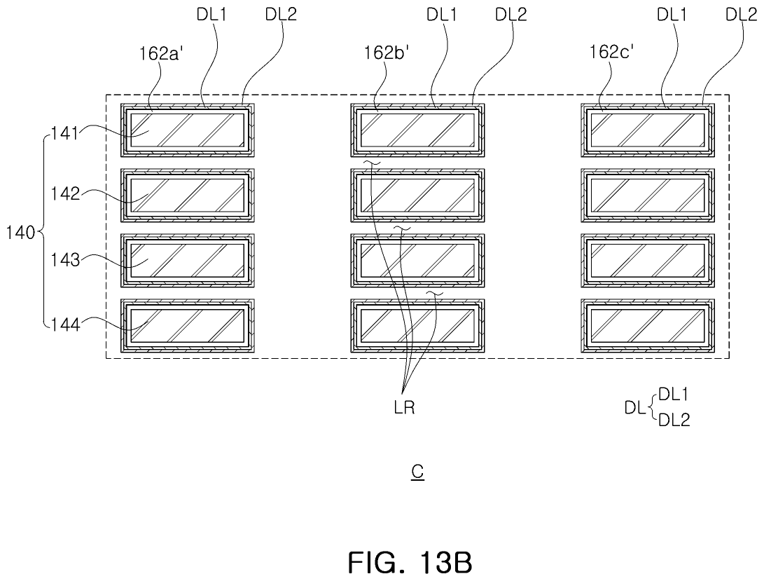

Referring to FIGS. 13A and 13B together with FIGS. 6A and 6B, a plurality of dipole layers DL may be formed on the preliminary gate dielectric layers 162′ (S620).

The plurality of dipole layers DL may be formed to be on (e.g., to cover) the preliminary gate dielectric layers 162′ in the lower gap regions LR and the upper gap region UR. A plurality of dipole layers DL may be formed by forming the first dipole layer DL1 on (e.g., covering or overlapping) the preliminary gate dielectric layers 162′, and forming the second dipole layer DL2 on (e.g., covering or overlapping) the first dipole layer DL1. The first dipole layer DL1 may include a first dipole material D1, and the second dipole layer DL2 may include a second dipole material D2. Whether to form the first and second dipole layers DL1 and DL2, and the order of forming the first and second dipole layers DL1 and DL2 may be varied in example embodiments. In an example embodiment, the plurality of dipole layers DL may be configured as conductive layers. In an example embodiment, the forming of the first and second dipole layers DL1 and DL2 may be performed by a deposition process.

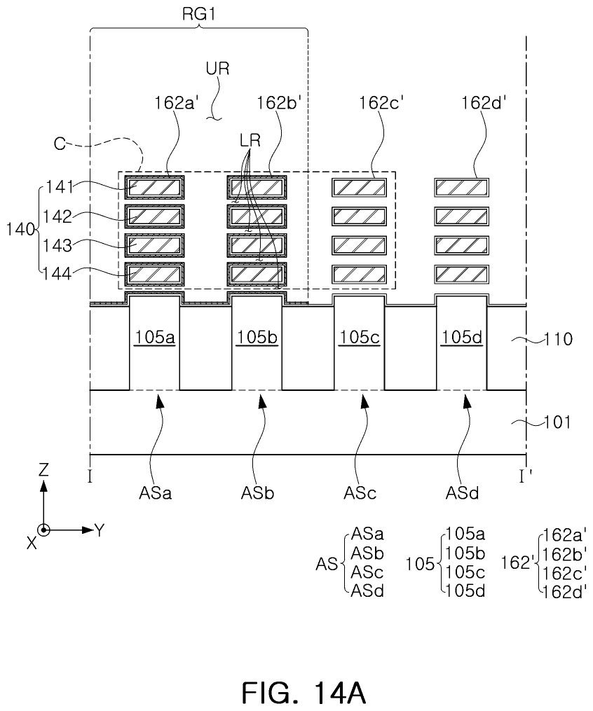

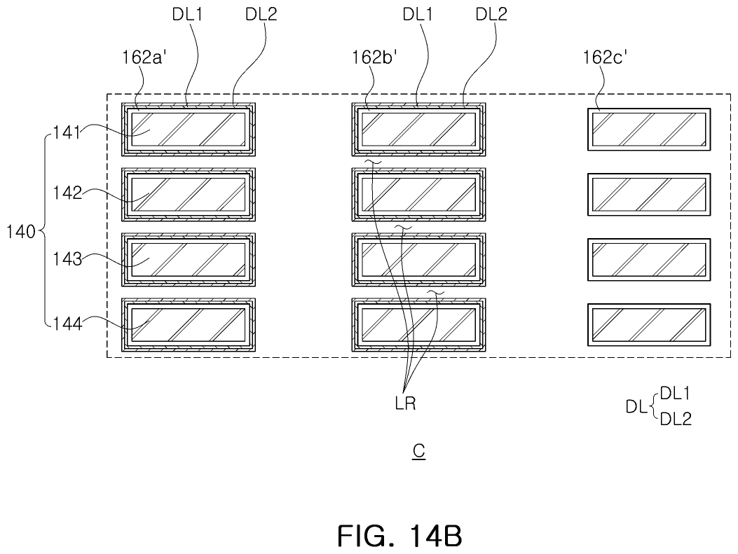

Referring to FIGS. 14A and 14B together with FIGS. 6A and 6B, the plurality of dipole layers DL in the regions other than a first region RG1 may be removed (S630).

In some embodiments, the first region RG1 may include at least two active structures AS, and a first blocking layer (not illustrated) for protecting the plurality of dipole layers DL (e.g., the first and second dipole layers DL1 and DL2) in the first region RG1 may be formed. For example, the first region RG1 may include a first active structure ASa and a second active structure ASb. In the regions other than the first region RG1 (e.g., in the region including only the third and fourth active structures ASc and ASd), the plurality of dipole layers DL (e.g., the first and second dipole layers DL1 and DL2) may be removed by the etching process, and the preliminary gate dielectric layers 162′ (e.g., the third and fourth preliminary gate dielectric layers 162c′, and 162d′) of the regions (e.g., the region including only the third and fourth active structures ASc and ASd) may be re-exposed to the lower gap region LR and the upper gap region UR. For example, the plurality of dipole layers DL (e.g., the first and second dipole layers DL1 and DL2) on the third active structure ASc and the fourth active structure ASd not included in the first region RG1 may be removed. The process of removing the plurality of dipole layers DL (e.g., the first and second dipole layers DL1 and DL2) may be, for example, a wet etching process.

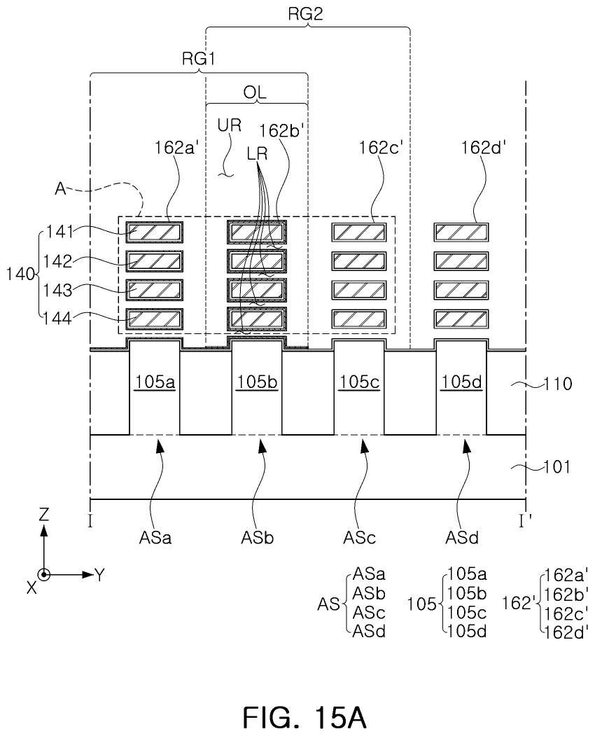

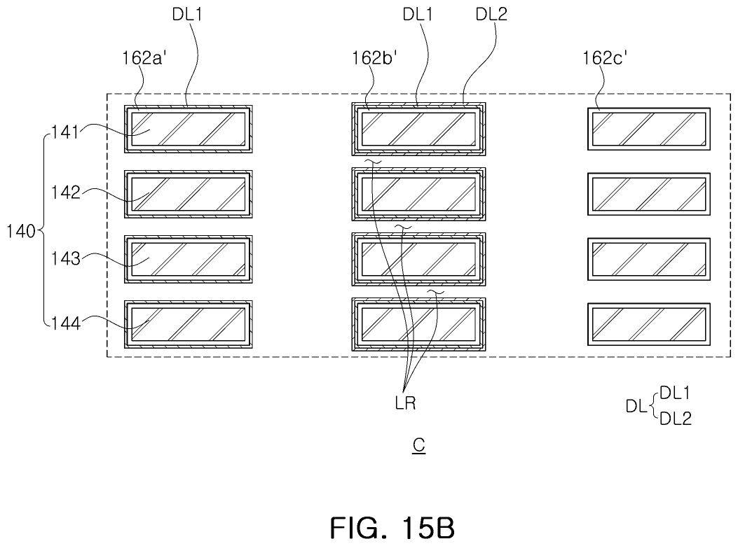

Referring to FIGS. 15A and 15B together with FIGS. 6A and 6B, the second dipole layer DL2 on the regions other than the second region RG2 may be removed (S640).

The second region RG2 may include at least two or more active structures AS (e.g., the second and third active structures ASb and ASc), and a second blocking layer (not illustrated) for protecting the plurality of dipole layers DL (e.g., the first and second dipole layers DL1 and DL2) (if any) in the second region RG2 may be formed. The second region RG2 may be formed such that an overlapping region OL overlapping the first region RG1 is present therein, and the overlapping region OL may include at least one active structure AS (e.g., the second active structure ASb). For example, the second region RG2 may include the second active structure ASb and the third active structure ASc, and the overlapping region OL may include the second active structure ASb. In the regions other than the second region RG2, the second dipole layer DL2 may be removed. For example, the second dipole layer DL2 on the first active structure ASa may be removed, and the first dipole layer DL1 on the first active structure ASa may remain and may be exposed to the lower gap regions LR and the upper gap region UR.

By the S620. S630, and S640 processes, the first dipole layer DL1 may be (may remain) on the first preliminary gate dielectric layer 162a′, the first and second dipole layers DL1 and DL2 may be (may remain) on the second preliminary gate dielectric layer 162b′, and the first and second dipole layers DL1 and DL2 may not be (may not remain) on the third preliminary gate dielectric layer 162c′ and the fourth preliminary gate dielectric layer 162d′.

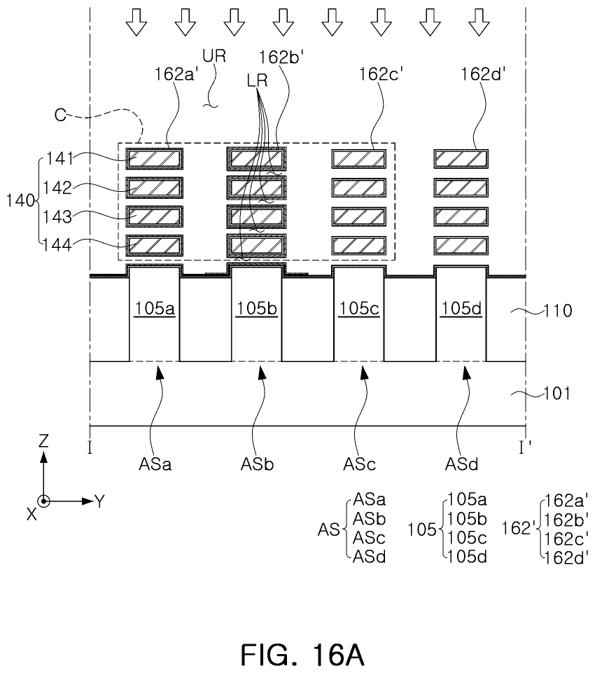

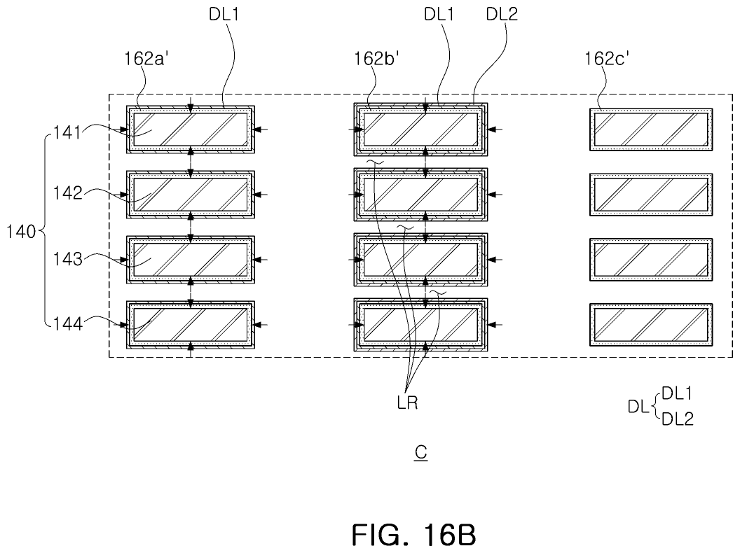

Referring to FIGS. 16A and 16B together with FIGS. 6A and 6B, the plurality of dipole materials D1 and D2 may diffuse into the preliminary gate dielectric layers 162′ through a heat treatment process (S650).

The heat treatment process may be performed, for example, at a temperature of (about) 800° C. to 1,000° C. Through the heat treatment process, the first and second dipole materials D1 and D2 in the first and second dipole layers DL1 and DL2 may diffuse into the adjacent (corresponding) preliminary gate dielectric layer 162′. In an example embodiment, the first and second dipole materials D1 and D2 may diffuse into a vacancy in the adjacent (corresponding) preliminary gate dielectric layer 162′. According to this process, the first dipole material D1 may be spread (e.g., diffused) into the first preliminary gate dielectric layer 162a′, and the first and second dipole materials D1 and D2 may be spread (e.g., diffused) into the second preliminary gate dielectric layer 162b′. The first and second dipole materials D1 and D2 may not spread (e.g., not diffused) in the third preliminary gate dielectric layer 162c′ and the fourth preliminary gate dielectric layer 162d′ from which the first and second dipole layers DL1 and DL2 have been removed.

Referring to FIGS. 17A, 17B, and 17C together with FIGS. 6A and 6B, the plurality of dipole layers DL1 and DL2 may be removed (S660).

After the heat treatment process, the plurality of dipole layers DL (e.g., the first and second dipole layers DL1 and DL2) may be removed. Accordingly, the first, second, third, and fourth gate dielectric layers 162a, 162b, 163c, and 164d including different amounts of the first and second dipole materials D1 and D2 or not including the first and second dipole materials D1 and D2 may be formed.

FIG. 17C illustrates the first and second dipole materials D1 and D2 included in the first, second, and third gate dielectric layers 162a, 162b, and 162c. In the description below, the example embodiment will be described with reference to the views described above. The embodiment of the first and second dipole materials D1 and D2 illustrated in FIG. 17C may be schematically described for ease of description, and the amounts, ratios, concentrations, atomic fraction, mass fraction, or the like, of the first dipole material D1 and the second dipole material D2 are not limited thereto.

During the heat treatment process (S650), the first dipole layer DL1 may remain on the first preliminary gate dielectric layer 162a′, such that a relatively large (larger) amount of first dipole material D1 may diffuse into the first preliminary gate dielectric layer 162a′, and the first gate dielectric layer 162a may include a relatively large (larger) amount of the first dipole material D1. In example embodiments, the second dipole material D2 in the second dipole layer DL2 formed on the first preliminary gate dielectric layer 162a′ before the heat treatment process may diffuse into a portion of the first preliminary gate dielectric layer 162a′ (before the removal of the second dipole layer DL2 on the first preliminary gate dielectric layer 162a′), and accordingly, the first gate dielectric layer 162a may also include the second dipole material D2. However, a (significantly) smaller amount of the second dipole material D2 may be present in the first gate dielectric layer 162a than the first dipole material D1. In example embodiments, the first gate dielectric layer 162a may not include the second dipole material D2.

During the heat treatment process (S650), both the first dipole layer DL1 and the second dipole layer DL2 may remain on the second preliminary gate dielectric layer 162b′, such that a relatively large amount of the first dipole material D1 and the second dipole material D2 may diffuse into the second preliminary gate dielectric layer 162b′, and the second gate dielectric layer 162b may include a relatively large (larger) amount of the first dipole material D1 and the second dipole material D2.

During the heat treatment process (S650), the first dipole layer DL1 and the second dipole layer DL2 may not remain on the third preliminary gate dielectric layer 162c′ and the fourth preliminary gate dielectric layer 162d′, such that the first dipole material D1 and the second dipole material D2 may not diffuse into the third preliminary gate dielectric layer 162c′ and the fourth preliminary gate dielectric layer 162d′. In some embodiments, before the first and second dipole layers DL1 and DL2 on the third preliminary gate dielectric layer 162c′ and the fourth preliminary gate dielectric layer 162d′ are removed, a portion of the first and second dipole materials D1 and D2 may diffuse into the third preliminary gate dielectric layer 162c′ and the fourth preliminary gate dielectric layer 162d′, and the third gate dielectric layer 162c and the fourth gate dielectric layer 162d may include a (relatively small or smaller) portion of the first and second dipole materials D1 and D2. An atomic fraction of the first and second dipole materials D1 and D2 included in the third gate dielectric layer 162c and the fourth gate dielectric layer 162d may be significantly smaller than an atomic fraction of the first and second dipole materials D1 and D2 included in the second gate dielectric layer 162b. In example embodiments, the third gate dielectric layer 162c and the fourth gate dielectric layer 162d may not include the first and second dipole materials D1 and D2.

Consequently, in this process of forming the gate dielectric layers 162 (S600), the first gate dielectric layer 162a may include a relatively large (larger) amount of the first dipole material D1, and the second gate dielectric layer 162b may include a relatively large (larger) amount of both the first dipole material D1 and the second dipole material D2. Accordingly, in some embodiments, the second gate dielectric layer 162b may maintain to have electrically similar (or the same) properties to those of the third gate dielectric layer 162c and the fourth gate dielectric layer 162d including a relatively small (smaller) amount of the first and second dipole materials D1 and D2 or (almost) no first and second dipole materials D1 and D2. Accordingly, the process of selectively shifting the threshold voltage of the first transistor TRa in one direction may be performed only on the first gate dielectric layer 162a without affecting electrical properties of the second, third, and fourth gate dielectric layers 162b, 162c, and 162d.

In example embodiments, from a process of forming a plurality of dipole layers (S620) to a process of removing a plurality of dipole layers (S660) may be performed repeatedly. The repetition of processes is not specifically illustrated in the drawing, but for example, in order for the second gate dielectric layer 162b to further include the second dipole material D2, the subsequent process as below may be further performed after the process S660.

Forming the second dipole layer DL2 and the first dipole layer DL1 in order—removing the second dipole layer DL2 and the first dipole layer DL1 of the regions other than the third region including the second active structure AS2 and the third active structure AS3—removing the first dipole layer DL1 from the regions other than the fourth region including the third active structure AS3 and the fourth active structure AS4 (the overlapping region includes the third active structure AS3)—a heat treatment process, may be performed.

According to the subsequent process, the second gate dielectric layer 162b may further include the second dipole material D2, such that a threshold voltage of the second transistor TRb may be shifted in a negative direction. Since the first dipole material D1 and the second dipole material D2 diffuse together in the third gate dielectric layer 162c, (substantially) the same or similar electrical characteristics as before the subsequent process may be maintained (in the third transistor TRc).

In this case, as described in FIGS. 1A, 1B, and 1C, in an example embodiment, a N-type first transistor TRa of which the threshold voltage is shifted in a positive direction, a P-type second transistor TRb of which the threshold voltage is shifted in a negative direction, a P-type third transistor of which an absolute value of the threshold voltage is smaller than that of the second transistor TRb, and an N-type fourth transistor of which an absolute value of the threshold voltage is smaller than that of the first transistor TRa may be formed.

As a semiconductor device has been highly integrated, process difficulty and process costs of removing dipole layers (DL) in the other regions while selectively protecting dipole layers (DL) on an active structure AS may increase. In example embodiments, each of the first region RG1 and the second region RG2 may include a plurality of active structures (AS), and an overlapping region OL overlapping the first region RG1 and the second region RG2 may be present, and the overlapping region OL may include at least one active structure (AS) such that process difficulty and process costs may be reduced.

Thereafter, referring to FIGS. 1B and IC together, the gate electrode 165 may be formed to (at least partially) fill the upper gap regions UR and the lower gap regions LR. The gate electrode 165 may be removed from the upper gap regions UR to a predetermined depth from an upper portion along with gate dielectric layers 162 and gate spacer layers 164. Accordingly, gate structures 160 including the gate dielectric layers 162, the gate electrode 165, and the gate spacer layers 164, respectively, may be formed.

The gate dielectric layers 162, the gate electrode 165, and the gate spacer layers 164 may be formed to continuously extend in the Y-direction and may be removed from a portion of regions by an etching process. Accordingly, the gate structures 160 separated from each other in the X-direction may be formed. To isolate the gate structure 160, a gate isolation pattern 180 such as the semiconductor device 100A in FIG. 3 may be formed.

Hereinafter, descriptions overlapping the description of the manufacturing method described above may not be provided.

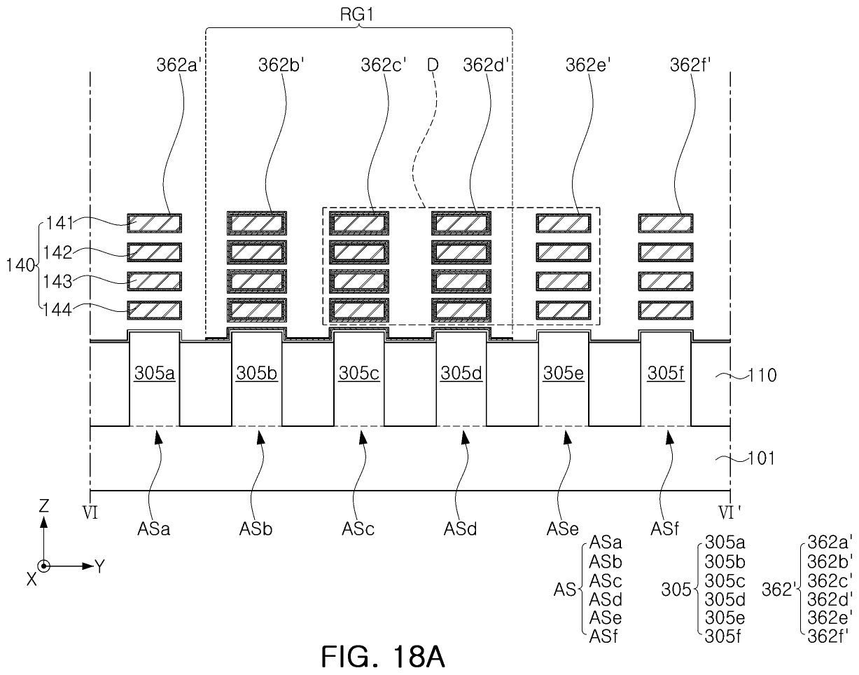

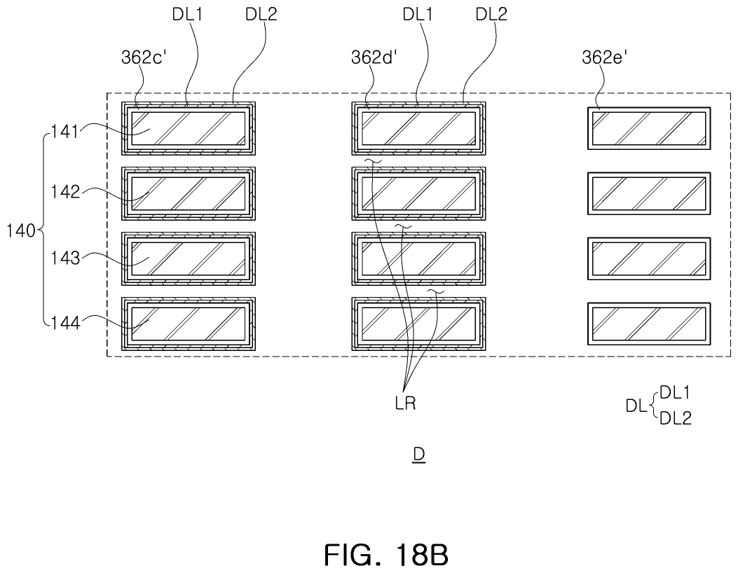

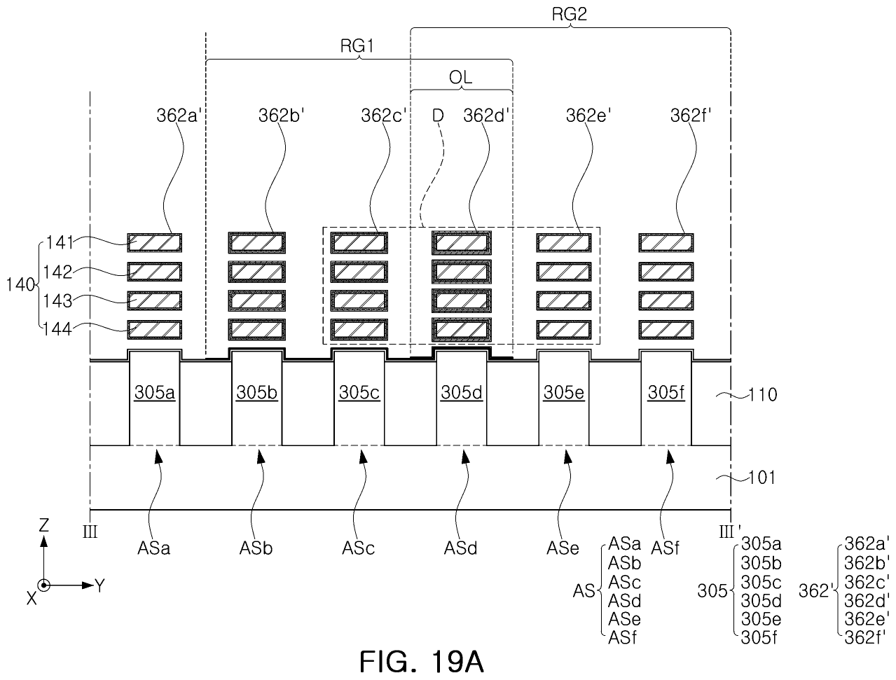

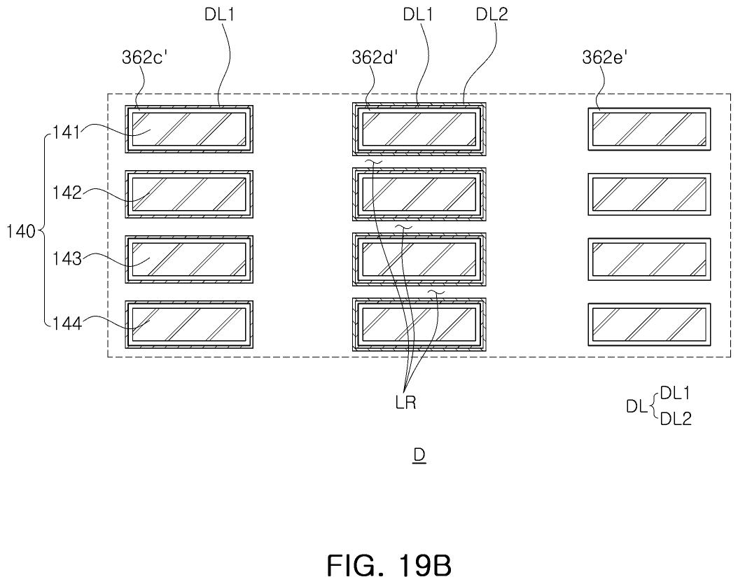

FIGS. 18A and 19A are cross-sectional views illustrating processes of a method of manufacturing a semiconductor device in order according to example embodiments. FIGS. 18A and 19A illustrate the regions corresponding to FIG. 5B.

FIGS. 18B and 19B are enlarged views illustrating a semiconductor device according to example embodiments. FIGS. 18B and 19B illustrate region “D” in FIGS. 18A and 19A, respectively, in an enlarged manner.

Referring to FIGS. 18A, 18B, 19A, and 19B, differently from FIGS. 14A, 14B, 15A, and 15B, processes may be performed such that a first region RG1 may include second, third, and fourth active structures ASb, ASc, and ASd, and a second region RG2 may include fourth, fifth, and sixth active structures ASd, ASe, and ASf, such that an overlapping region OL may include the fourth active structure ASd. Accordingly, referring to FIG. 19B, the first dipole layer DL1 may remain on the third preliminary gate dielectric layer 362c′, and the first and second dipole layers DL1 and DL2 may remain on the fourth preliminary gate dielectric layer 362d′. Thereafter, through a heat treatment process, the first dipole material D1 of the first dipole layer DL1 may be expanded (e.g., diffused) in the third preliminary gate dielectric layer 362c′, and the first dipole material D1 of the first dipole layer DL1 and the second dipole material D2 of the second dipole layer DL2 may be expanded (e.g., diffused) in the fourth preliminary gate dielectric layer 362d′. Thereafter, according to the subsequent process, the semiconductor device 100C in FIG. 5B may be manufactured. In the range in which each of the first region RG1 and the second region RG2 include a plurality of active structures AS, and the overlapping region OL at which the regions overlap each other is present, the number of active structures AS included in the first region RG1, the second region RG2 and the overlapping region OL may be varied. For example, in an example embodiment, the processes may be performed such that the first region RG1 may include the third and fourth active structures ASc and ASd, the second region RG2 may include the fourth and fifth active structures ASd and ASe, and the overlapping region OL may include the fourth active structure ASd. In some embodiments, in an example embodiment, the process may be performed such that the first region RG1 and the second region RG2 include four or more active structures.

According to the aforementioned example embodiments, by providing various operating voltages by varying the gate dielectric layer of transistors, a semiconductor device having improved electrical properties may be provided, and a method of manufacturing a semiconductor device, which has reduced process difficulty and process costs, may be provided.

While the inventive concept has been particularly shown and described with reference to embodiments thereof, it will be understood that various changes in form and details may be made therein without departing from the scope of the following claims.

1. A method of manufacturing a semiconductor device, the method comprising:
preparing a substrate including a plurality of active structures spaced apart from each other in a first direction;
forming preliminary gate dielectric layers on at least a portion of the plurality of active structures;
forming a plurality of dipole layers by forming a first dipole layer including a first dipole material and a second dipole layer including a second dipole material on the preliminary gate dielectric layers;
removing the plurality of dipole layers in regions other than a first region of the plurality of active structures, wherein the first region includes at least two active structures among the plurality of active structures;
removing a portion of the second dipole layer in regions other than a second region of the plurality of active structures, wherein the second region includes at least two active structures among the plurality of active structures, and the first region and the second region overlap each other to form an overlapping region;
performing a heat treatment process of diffusing the first dipole material in the first dipole layer and the second dipole material in the second dipole layer into corresponding preliminary gate dielectric layers among the preliminary gate dielectric layers; and
forming a gate structure by removing the plurality of dipole layers and forming a gate electrode,
wherein the overlapping region includes at least one of the plurality of active structures, and
wherein the first direction is parallel with an upper surface of the substrate.

2. The method of claim 1,
wherein the plurality of active structures includes first, second, third, and fourth active structures spaced apart from each other in the first direction,
wherein the first region includes the first active structure and the second active structure,
wherein the second region includes the second active structure and the third active structure, and
wherein the overlapping region includes the second active structure.

3. The method of claim 2,
wherein the preliminary gate dielectric layers include a first preliminary gate dielectric layer formed on the first active structure, a second preliminary gate dielectric layer formed on the second active structure, a third preliminary gate dielectric layer formed on the third active structure, and a fourth preliminary gate dielectric layer formed on the fourth active structure,
wherein, in the heat treatment process,
the first dipole material is diffused into the first preliminary gate dielectric layer,
the first dipole material and the second dipole material are diffused into the second preliminary gate dielectric layer, and
wherein the first dipole material and the second dipole material do not diffuse into the third preliminary gate dielectric layer and the fourth preliminary gate dielectric layer.

4. The method of claim 3,
wherein the substrate includes an N-type Metal Oxide Semiconductor Field Effect Transistor (NMOSFET) region including the first active structure and the fourth active structure, and a P-type Metal Oxide Semiconductor Field Effect Transistor (PMOSFET) region including the second active structure and the third active structure,
wherein the first dipole material is configured to shift a threshold voltage of a transistor in a positive direction, and
wherein the second dipole material is configured to shift a threshold voltage of a transistor in a negative direction.

5. The method of claim 3,
wherein the substrate includes an N-type Metal Oxide Semiconductor Field Effect Transistor (NMOSFET) region including the first active structure and the second active structure, and a P-type Metal Oxide Semiconductor Field Effect Transistor (PMOSFET) region including the third active structure and the fourth active structure,
wherein the first dipole material is configured to shift a threshold voltage of a transistor in a positive direction, and
wherein the second dipole material is configured to shift a threshold voltage of a transistor in a negative direction, and
wherein, after the performing the heat treatment process, a difference between an atomic fraction of the first dipole material in the second preliminary gate dielectric layer and an atomic fraction of the second dipole material in the second preliminary gate dielectric layer is smaller than an atomic fraction of the first dipole material in the first preliminary gate dielectric layer.

6. The method of claim 4,
wherein the first dipole material includes aluminum (Al), tantalum (Ta), tungsten (W), manganese (Mn), chromium (Cr), ruthenium (Ru), platinum (Pt), gallium (Ga), germanium (Ge), and/or gold (Au), and
wherein the second dipole material includes lanthanum (La), gadolinium (Gd), lutetium (Lu), yttrium (Y), and/or scandium (Sc).

7. The method of claim 1,
wherein the substrate includes N-type Metal Oxide Semiconductor Field Effect Transistor (NMOSFET) regions and P-type Metal Oxide Semiconductor Field Effect Transistor (PMOSFET) regions disposed alternately in the first direction,
wherein each of the plurality of active structures is in respective one of the NMOSFET regions or respective one of the PMOSFET regions, and
wherein at least one of the first region and the second region includes a first active structure among the plurality of active structures in the respective one of the NMOSFET regions and a second active structure among the plurality of active structures in the respective one of the PMOSFET regions.

8. The method of claim 7,
wherein each of the NMOSFET regions and the PMOSFET regions includes two active structures among the plurality of active structures, and
wherein the overlapping region consists of one of the plurality of active structures.

9. The method of claim 1,
wherein each of the plurality of active structures includes an active region and a plurality of channel layers spaced apart from each other in a second direction on the active region,
wherein the preliminary gate dielectric layers are on an upper surface of the active region and the plurality of channel layers of each of the plurality of active structures, and
wherein the second direction is perpendicular to the upper surface of the substrate.

10. A method of manufacturing a semiconductor device, the method comprising:
preparing a substrate including a first active structure, a second active structure, a third active structure, and a fourth active structure spaced apart from each other in a first direction;
forming a first gate dielectric layer on at least a portion of the first active structure, a second gate dielectric layer on at least a portion of the second active structure, a third gate dielectric layer on at least a portion of the third active structure, and a fourth gate dielectric layer on at least a portion of the fourth active structures; and
forming a gate electrode extending around the first, second, third, and fourth gate dielectric layers,
wherein the first gate dielectric layer includes a first dipole material,
wherein the second gate dielectric layer includes a second dipole material different from the first dipole material, and
wherein the first direction is parallel with an upper surface of the substrate.

11. The method of claim 10,
wherein the first active structure includes a first active region including P-type impurities,
wherein the first dipole material is configured to shift a threshold voltage of a transistor in a positive direction, and
wherein the second dipole material is configured to shift a threshold voltage of a transistor in a negative direction.

12. The method of claim 11, wherein the second active structure includes a second active region including N-type impurities.

13. The method of claim 12,
wherein the second gate dielectric layer further includes the first dipole material, and
wherein an atomic fraction of the first dipole material in the second gate dielectric layer is smaller than an atomic fraction of the second dipole material in the second gate dielectric layer.

14. The method of claim 12,
wherein the third active structure includes a third active region including N-type impurities, and
wherein the fourth active structure includes a fourth active region including P-type impurities.

15. The method of claim 11,
wherein the first dipole material includes aluminum (Al), tantalum (Ta), tungsten (W), manganese (Mn), chromium (Cr), ruthenium (Ru), platinum (Pt), gallium (Ga), germanium (Ge), and/or gold (Au), and
wherein the second dipole material includes lanthanum (La), gadolinium (Gd), lutetium (Lu), yttrium (Y), and/or scandium (Sc).

16. The method of claim 10,
wherein the first active structure includes a first active region including N-type impurities,
wherein the second active structure includes a second active region including P-type impurities,
wherein the first dipole material is configured to shift a threshold voltage of a transistor in a negative direction, and
wherein the second dipole material is configured to shift a threshold voltage of a transistor in a positive direction.

17. The method of claim 16,
wherein the second gate dielectric layer further includes the first dipole material, and
wherein an atomic fraction of the first dipole material in the second gate dielectric layer is smaller than an atomic fraction of the second dipole material in the second gate dielectric layer.

18. The method of claim 10,
wherein the second gate dielectric layer further includes the first dipole material, and
wherein a difference between an atomic fraction of the first dipole material in the second gate dielectric layer and an atomic fraction of the second dipole material in the second gate dielectric layer is smaller than an atomic fraction of the first dipole material in the first gate dielectric layer.

19. A method of manufacturing a semiconductor device, the method comprising:
alternately forming a plurality of sacrificial layers and a plurality of channel layers on a substrate;
forming a plurality of active structures by partially removing the plurality of channel layers, the plurality of sacrificial layers, and the substrate, wherein each of the plurality of active structures includes an active region extending in a first direction parallel with an upper surface of the substrate;
forming a sacrificial gate structure and gate spacer layers extending in a second direction intersecting the first direction on the plurality of active structures, wherein the second direction is parallel with the upper surface of the substrate;
forming recess regions by removing a portion of each of the plurality of active structures exposed from the sacrificial gate structure, and forming source/drain regions in the recess regions;
removing the sacrificial gate structures and the plurality of sacrificial layers; and
forming a gate structure extending in the second direction on the active region in the each of the plurality of active structures,
wherein the forming the gate structure includes:
forming preliminary gate dielectric layers extending around the plurality of channel layers;
forming a first dipole layer and a second dipole layer conformally extending along the preliminary gate dielectric layers in order;
forming a first blocking layer in a first region of the plurality of active structures, and removing the first dipole layer and the second dipole layer from other regions of the plurality of active structures in which the first blocking layer is absent;
removing the first blocking layer, forming a second blocking layer in a second region of the plurality of active structures, wherein the first region and the second region overlap each other to form an overlapping region, and removing the second dipole layer from other regions of the plurality of active structures in which the second blocking layer is absent, wherein the overlapping region includes at least one of the plurality of active structures;
removing the second blocking layer, performing a heat treatment process of diffusing a first dipole material in the first dipole layer and a second dipole material in the second dipole layer into corresponding preliminary gate dielectric layers among the preliminary gate dielectric layers; and
removing both the first dipole layer and the second dipole layer.

20. The method of claim 19,
wherein the first dipole material is configured to shift a threshold voltage of a transistor in a positive direction, and
wherein the second dipole material is configured to shift a threshold voltage of a transistor in a negative direction.

21-29. (canceled)
